(19) United States
(12) Patent Application Publication
(10) Pub. No.: US 2017/0186704 A1
(43) Pub. Date: Jun. 29, 2017

(54) METHOD FOR MANUFACTURING A SEMICONDUCTOR DEVICE HAVING MOISTURE-RESISTANT RINGS BEING FORMED IN A PERIPHERAL REGION

(71) Applicant: MIE FUJITSU SEMICONDUCTOR LIMITED, Kuwana-shi (JP)

(72) Inventors: Jun Sakuma, Yokohama-shi (JP); Hideaki Matsumura, Yokohama-shi (JP); Tadashi Ohshima, Yokohama-shi (JP)

(73) Assignee: MIE FUJITSU SEMICONDUCTOR LIMITED, Kuwana-shi (JP)

(21) Appl. No.: 15/459,199

(22) Filed: Mar. 15, 2017

Related U.S. Application Data
(62) Division of application No. 14/286,253, filed on May 23, 2014.
Application No. 14/286,253 is a division of application No. 12/749,018, filed on Mar. 29, 2010, now abandoned.

(30) Foreign Application Priority Data
Mar. 31, 2009 (JP) 2009-84638

(51) Int. Cl. H01L 23/00; H01L 23/58

(52) U.S. Cl. CPC H01L 23/562; H01L 23/585; H01L 23/564

(57) ABSTRACT

A semiconductor device includes a first moisture-resistant ring disposed in a peripheral region surrounding a circuit region on a semiconductor substrate in such a way as to surround the circuit region and a second moisture-resistant ring disposed in the peripheral region in such a way as to surround the first moisture-resistant ring.

### CROSS-REFERENCE TO RELATED APPLICATIONS

This application is a divisional of U.S. application. Ser. No. 14/286,253 filed on May 23, 2014, which is a divisional of U.S. application Ser. No. 12/749,018 filed Mar. 29, 2010, now abandoned, which is based upon and claims the benefit of priority of the prior Japanese Patent Application No. 2009-84638, filed on Mar. 31, 2009 the entire contents of which are incorporated herein by reference.

### FIELD

The present invention relates to a semiconductor device and a method for manufacturing the semiconductor device.

### BACKGROUND

A moisture-resistant ring to prevent intrusion of moisture from the outside is disposed in a peripheral region around a circuit region, in which semiconductor elements, multilayer wiring structures, and the like are disposed.

In order to simplify production steps, each pattern for forming the moisture-resistant ring is formed by using the same electrically conductive film as that for a multilayer wiring and the like disposed in the circuit region.

However, a pattern constituting a part of the moisture-resistant ring may be peeled. If the pattern constituting a part of the moisture-resistant ring is peeled, intrusion of moisture into the circuit region is not always prevented sufficiently.

Consequently, realization of technology for preventing peeling of a pattern serving as a part of the moisture-resistant ring has been desired.

### SUMMARY

According to one aspect of the invention, a semiconductor device includes a first moisture-resistant ring disposed in a peripheral region surrounding a circuit region on a semiconductor substrate in such a way as to surround the circuit region and a second moisture-resistant ring disposed in the peripheral region in such a way as to surround the first moisture-resistant ring.

The first moisture-resistant ring has a first pattern buried in a first insulating layer disposed on the semiconductor substrate; a second pattern, which is buried in a second insulating layer disposed on the first insulating layer, which is connected to the first pattern, and which has a width smaller than the width of the first pattern; and a third pattern, which is disposed on the second insulating layer, which is connected to the second pattern, and in which at least one of two side portions along a longitudinal direction do not overlap the first pattern two-dimensionally.

The second moisture-resistant ring has a fourth pattern buried in the first insulating layer; a fifth pattern, which is buried in the second insulating layer, which is connected to the fourth pattern, and which has a width smaller than the width of the fourth pattern; and a sixth pattern, which is disposed on the second insulating layer, which is connected to the fifth pattern, in which at least one of two side portions along the longitudinal direction do not overlap the fourth pattern, and which is isolated from the third pattern two-dimensionally.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a sectional view illustrating a semiconductor device according to a first embodiment.

FIG. 2 is a plan view illustrating a part of a semiconductor wafer before dicing is conducted.

FIG. 3 is a plan view illustrating a semiconductor device after dicing into individual pieces is conducted.

FIG. 4 is a plan view along a line B-B′ illustrated in FIG. 2.

FIG. 5 is a magnified plan view of a portion in a circle C illustrated in FIG. 3.

FIG. 6 is a plan view illustrating a semiconductor wafer before dicing is conducted.

FIG. 7 is a sectional view illustrating the case where an interlayer insulating film exposed at the peripheries of ring patterns has been removed excessively.

FIGS. 8A and 8B are sectional views illustrating the states in which a solder bump or a bonding wire is connected to a semiconductor device according to the first embodiment.

FIGS. 9A to 9T are sectional views illustrating steps of a method for manufacturing semiconductor device according to the first embodiment.

FIGS. 10A and 10B are sectional views illustrating the states in which an upper layer portion of an interlayer insulating film is removed through polishing to a relatively large extent.

FIG. 11 is a sectional view illustrating the state in which an upper layer portion of an interlayer insulating film is removed through not only polishing, but also etching to a relatively large extent.

FIG. 12 is a sectional view illustrating a semiconductor device according to a second embodiment.

FIG. 13 is a plan view illustrating a part of a semiconductor device according to the second embodiment.

FIG. 14 is a sectional view illustrating the state in which an upper layer portion of an interlayer insulating film is removed through not only polishing, but also etching to a relatively large extent.

FIG. 15 is a plan view illustrating a semiconductor device according to a third embodiment.

FIG. 16 is a magnified plan view of a portion in a circle D illustrated in FIG. 15.

FIG. 17 is a plan view illustrating a semiconductor device according to a modified embodiment of the third embodiment.

FIGS. 18A and 18B are sectional views illustrating the states in which a surface of an interlayer insulating film exposed at the periphery of a ring pattern has been removed.

### DETAILED DESCRIPTION OF THE EMBODIMENTS

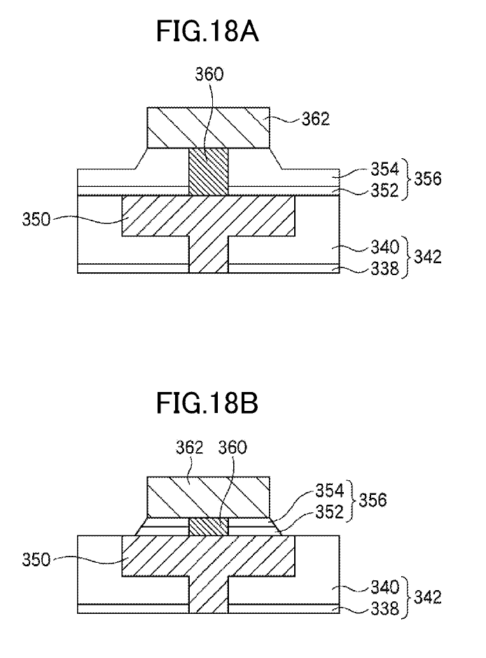

FIGS. 18A and 18B are sectional views illustrating the states in which a surface of an interlayer insulating film exposed at the periphery of a ring pattern serving as a part of a moisture-resistant ring has been removed. In this regard, FIGS. 18A and 18B illustrate merely an upper layer portion of a plurality of layers of ring patterns laminated on the semiconductor substrate.

As shown in FIG. 18A, for example, a ring pattern 350 is disposed in an interlayer insulating film 342 formed by laminating an insulating film 338 and an insulating film 340. For example, copper (Cu) is used as the material for the ring pattern 350. The ring pattern 350 is extended in a direction perpendicular to the drawing illustrated in FIGS. 18A and 18B. The width of an upper portion in the ring pattern 350 is specified to be relatively large. The width of a lower portion in the ring pattern 350 is specified to be relatively small. An interlayer insulating film 356 formed by laminating an insulating film 352 and insulating film 354 is disposed on the interlayer insulating film 342, in which the ring pattern 350 is buried. A ring pattern 360 connected to the ring pattern 350 is buried in the interlayer insulating film 356. For example, tungsten (W) is used as the material for the ring pattern 360. In a manner similar to that of the ring pattern 350, the ring pattern 360 is extended in the direction perpendicular to the drawing illustrated in FIGS. 18A and 18B. A ring pattern 362 is disposed on the interlayer insulating film 356, in which the ring pattern 360 is buried. For example, aluminum (Al) is used as the material for the ring pattern 362. In a manner similar to that of the ring pattern 360, the ring pattern 362 is extended in the direction perpendicular to the drawing illustrated in FIGS. 18A and 18B.

In formation of the ring pattern 362, for example, an aluminum film or the like is formed all over a surface, a photoresist film is formed on the aluminum film, and the aluminum film is etched by using the photoresist film as a mask, so that the ring pattern 362 is formed. At this time, over etching of the interlayer insulating film 356 may occur. Consequently, as illustrated in FIG. 18A, the thickness of a portion of the interlayer insulating film 356 exposed at the periphery of the ring pattern 362 may be reduced.

FIG. 18B is a sectional view illustrating the case where the thickness of a portion of the interlayer insulating film 356 exposed at the periphery of the ring pattern 362 has been reduced excessively. In the peripheral portion of the semiconductor wafer, when polishing is conducted through chemical mechanical polishing (CMP), a surface of the interlayer insulating film 356 tends to be cut to a relatively large extent. Consequently, as illustrated in FIGS. 18A and 18B, the thickness of the interlayer insulating film may become small. Furthermore, in the case where the adhesion between the insulating film 352 and the ring pattern 350 is not always good, peeling may occur between the insulating film 352 and the ring pattern 350, so that the ring patterns 360 and 362 may be peeled off the interlayer insulating film 342.

### First Embodiment

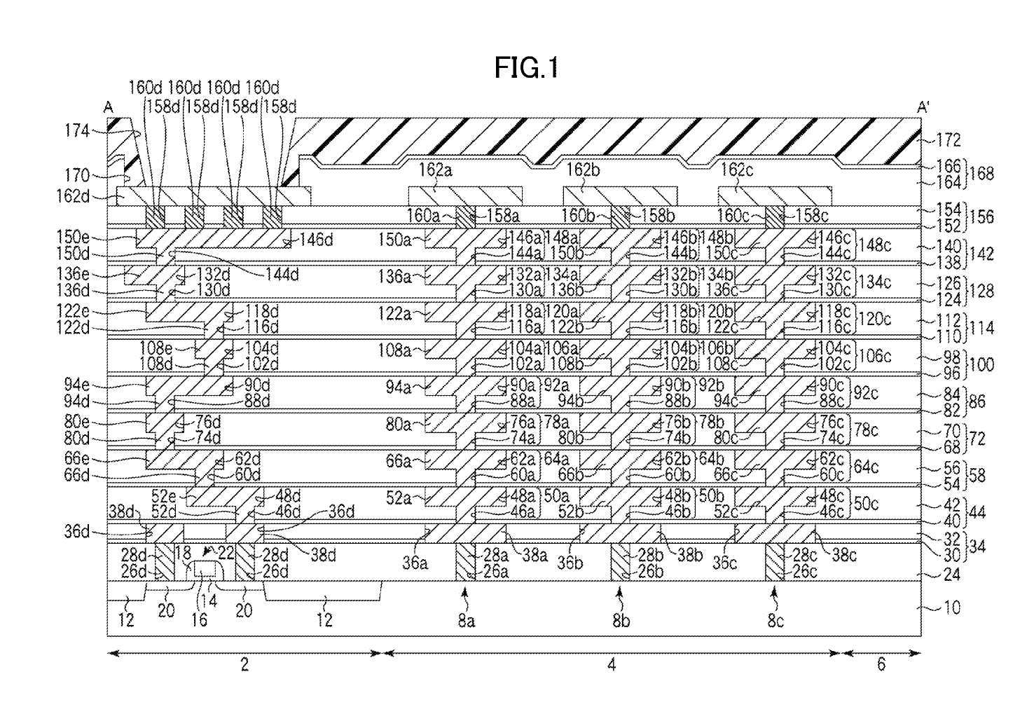

A semiconductor device and a method for manufacturing the semiconductor device according to a first embodiment will be described with reference to FIGS. 1 to 11.

(Semiconductor Device)

Initially, the semiconductor device according to the present embodiment will be described with reference to FIG. 1 to FIGS. 8A and 8B. FIG. 1 is a sectional view illustrating the semiconductor device according to the present embodiment.

The left region in the drawing illustrated in FIG. 1 is a circuit region (circuit-forming region, integrated circuit region) 2. The region surrounding the circuit region 2, that is, the region illustrated on the right side of the circuit region 2 in FIG. 1, is a peripheral region (sealing region) 4. The region surrounding the peripheral region 4, that is, the region illustrated on the right side of the peripheral region 4 in FIG. 1, is a scribe line region (scribe region, dicing region) 6.

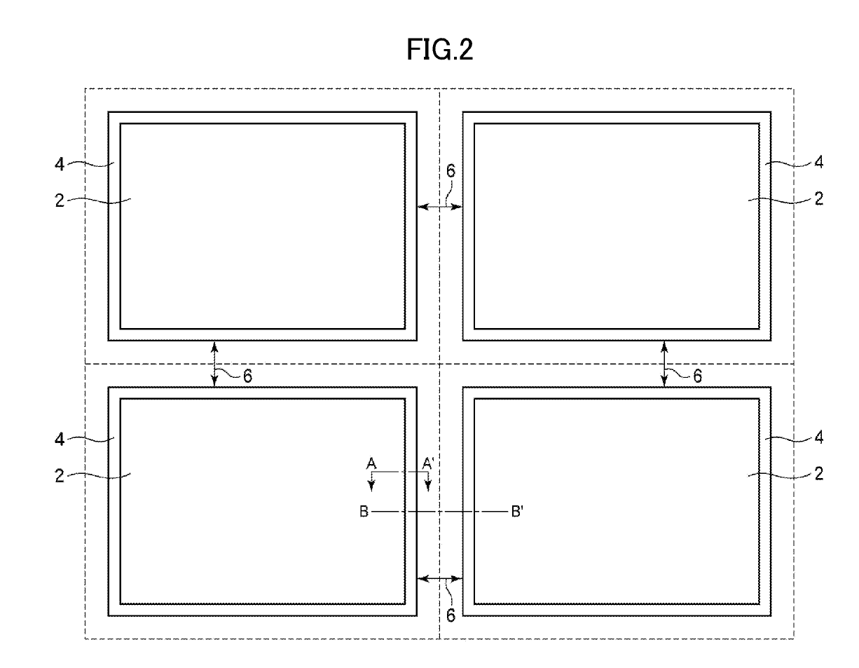

FIG. 2 is a plan view illustrating a part of a semiconductor wafer before dicing is conducted. In practice, many semiconductor devices are formed on the semiconductor wafer (semiconductor substrate). However, four semiconductor devices are illustrated in FIG. 2. Broken lines in FIG. 2 indicate center lines of the scribe line region 6. FIG. 1 corresponds to the section along the line A-A′ in FIG. 2. As illustrated in FIG. 2, the peripheral region 4 is the region surrounding the circuit region 2.

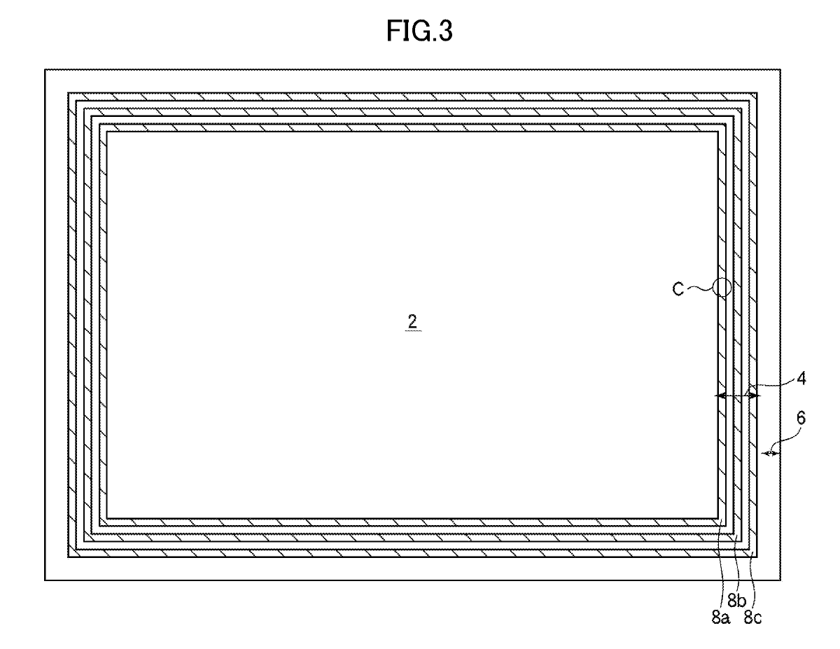

FIG. 3 is a plan view illustrating a semiconductor device after dicing into individual pieces is conducted. As illustrated in FIG. 3, in the peripheral region 4, moisture-resistant rings (guard ring, seal ring, moisture-resistant wall) 8a to 8c are disposed continuously. The moisture-resistant ring 8a is disposed innermostly in the peripheral region 4 and is disposed continuously in such a way as to surround the circuit region 2. The moisture-resistant ring 8b is disposed continuously in such a way as to surround the moisture-resistant ring 8a. The moisture-resistant ring 8c is disposed continuously in such a way as to surround the moisture-resistant ring 8b. In the present embodiment, a plurality of moisture-resistant rings 8a to 8c are disposed for the purpose of reliably preventing moisture from reaching the circuit region 2 side from the scribe line region 6 side.

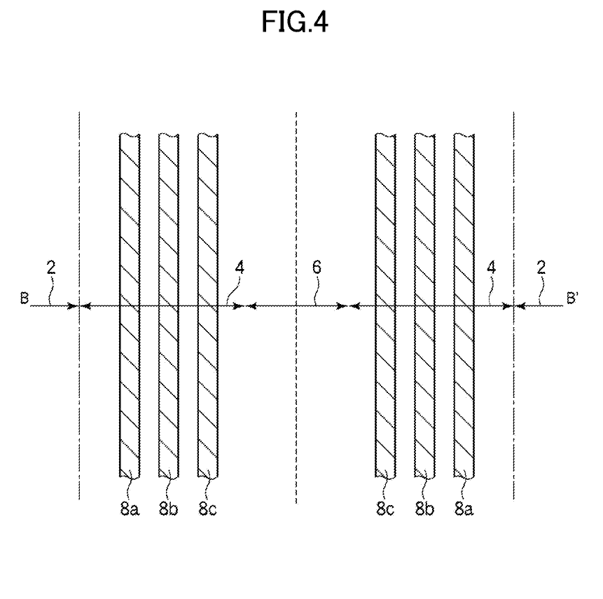

FIG. 4 is a plan view along a line B-B′ illustrated in FIG. 2. The broken line in FIG. 4 indicates a center line of the scribe line region 6. Alternate long and short dashed lines in FIG. 4 indicate boundaries between the peripheral regions (sealing region) 4 and the circuit regions 2.

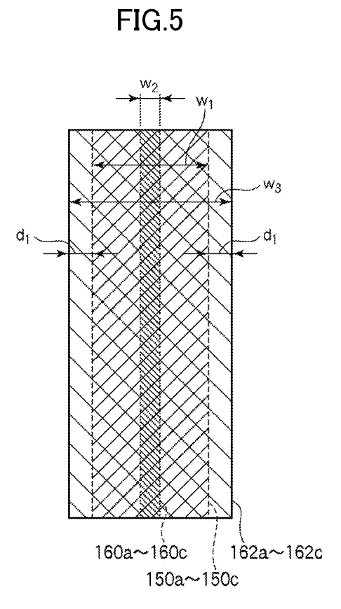

FIG. 5 is a magnified plan view of a portion in a circle C illustrated in FIG. 3.

As illustrated in FIG. 1, element isolation regions 12 to determine the element region are disposed on a semiconductor substrate 10. As for the semiconductor substrate 10, for example, a silicon substrate is used. The element isolation regions 12 is formed from, for example, silicon dioxide.

A gate electrode 16 is disposed on the semiconductor substrate 10 in the element region with a gate insulating film 14 therebetween. As for the material for the gate electrode 16, for example, polysilicon or the like is used. A side wall insulating film 18 is disposed on the side wall portion of the gate electrode 16. As for the side wall insulating film 18, for example, a silicon oxide film is used.

Source/drain diffusion layers 20 are disposed in the semiconductor substrate 10 on both sides of the gate electrode 16 provided with the side wall insulating film 18. In this manner, a transistor 22 including the gate electrode 16 and the source/drain diffusion layers 20 are disposed.

An interlayer insulating film 24 is disposed on the semiconductor substrate 10 provided with the transistor 22. The interlayer insulating film 24 is formed from a laminated film including, for example, a silicon nitride film (not illustrated in the drawing) and a phospho silicate glass (PSG) film (not illustrated in the drawing) disposed on the silicon nitride film. The film thickness of the silicon nitride film is specified to be, for example, about 30 nm. The film thickness of the PSG film is specified to be, for example, about 720 nm.

Grooves 26a to 26c reaching the semiconductor substrate 10 are disposed in the interlayer insulating film 24 in the peripheral region 4. The widths of the grooves 26a to 26c is specified to be, for example, about 0.10 μm. The grooves 26a to 26c are disposed in such a way as to surround the circuit region 2.

Contact holes 26d reaching the source/drain diffusion layers 20 are disposed in the interlayer insulating film 24 in the circuit region 2. The diameter of the contact hole 26d is specified to be, for example, about 0.12 μm.

A barrier metal film (not illustrated in the drawing) is disposed in each of the grooves 26a to 26c and in each of the contact holes 26d. The barrier metal film is formed by, for example, laminating a Ti film (not illustrated in the drawing) and a TiN film (not illustrated in the drawing) sequentially. The film thickness of the above-described Ti film is specified to be, for example, about 10 nm. The film thickness of the above-described TiN film is specified to be, for example, about 10 nm.

Ring patterns (ring-shaped pattern, moisture-resistant ring pattern) 28a to 28c serving as a part of moisture-resistant rings 8a to 8c are buried in the grooves 26a to 26c, respectively, provided with the barrier metal film. The ring patterns 28a to 28c are disposed in such a way as to surround the circuit region 2. The ring patterns 28a to 28c are connected to the semiconductor substrate 10.

A conductor plug 28d is buried in the contact hole 26d provided with the barrier metal film.

The conductor plugs 28d and the ring patterns 28a to 28c are formed from the same electrically conductive film. Here, as for the material for the conductor plugs 28d and the ring patterns 28a to 28c, for example, tungsten is used. The reason for the use of tungsten as the material for the conductor plugs 28d and the ring patterns 28a to 28c is that a tungsten film may be buried reliably into relatively fine grooves 26a to 26c and the contact holes 26d.

An insulating film (etching stopper film) 30 is disposed on the interlayer insulating film 24, in which the ring patterns 28a to 28c and the conductor plugs 28d are buried. As for the insulating film 30, for example, a SiC film (SiOC film) is used. The film thickness of the insulating film 30 is specified to be, for example, about 30 nm.

A laminated film 32 is disposed on the insulating film 30. The laminated film 32 is formed by laminating, for example, a SiOC film (not illustrated in the drawing) and a tetraethoxy silane (TEOS) film (not illustrated in the drawing) sequentially. The film thickness of the above-described SiOC film is specified to be, for example, about 130 nm. The film thickness of the above-described TEOS film is specified to be, for example, about 100 nm. The insulating film 30 and the laminated film 32 constitute an interlayer insulating film 34.

Grooves 36a to 36c exposing the surfaces of the ring patterns 28a to 28c are disposed in the interlayer insulating film 34 in the peripheral region 4. The grooves 36a to 36c are disposed in such a way as to surround the circuit region 2. The widths of the grooves 36a to 36c are specified to be larger than the widths of the grooves 26a to 26c. The widths of the grooves 36a to 36c are specified to be, for example, about 2.0 μm.

Grooves 36d, each exposing the upper surface of the conductor plug 28d, are disposed in the interlayer insulating film 34 in the circuit region 2. The widths of the grooves 36d are specified to be, for example, about 0.12 μm.

A barrier metal film (not illustrated in the drawing) is disposed in the grooves 36a to 36c and in the grooves 36d. As for the barrier metal film, for example, a tantalum (Ta) film is used. The film thickness of the barrier metal film is specified to be, for example, about 10 nm. The barrier metal film prevents diffusion of Cu used as a material for ring patterns 38a to 38c and wirings 38d.

Ring patterns 38a to 38c are buried in the grooves 36a to 36c provided with the barrier metal film. The ring patterns 38a to 38c are disposed in such a way as to surround the circuit region 2. The ring patterns 38a to 38c are connected to the ring patterns 28a to 28c, respectively.

The wirings 38d are buried in the grooves 36d provided with the barrier metal film. The wirings 38d are connected to the conductor plugs 28d.

The wirings 38d and the ring patterns 38a to 38c are formed from the same electrically conductive film. Here, as for the material for the wirings 38d and the ring patterns 38a to 38c, for example, copper (Cu) is used. The reason for the use of Cu as the material for the wiring 38d is that reduction in wiring resistance or the like is facilitated and a working speed of the semiconductor device is improved.

An insulating film (Cu diffusion-preventing film, cap film) 40 is disposed on the interlayer insulating film 34, in which the ring patterns 38a to 38c and the wirings 38d are buried. As for the insulating film 40, for example, a SiC film (SiOC film) is used. The film thickness of the insulating film 40 is specified to be, for example, about 55 nm. In the present embodiment, the SiC film is used as the material for the insulating film 40 because the SiC film may prevent diffusion of Cu and, in addition, facilitate an improvement in stress migration resistance.

A laminated film 42 is disposed on the insulating film 40. The laminated film 42 is formed by laminating, for example, a SiOC film (not illustrated in the drawing) and a TEOS film (not illustrated in the drawing) sequentially. The film thickness of the above-described SiOC film is specified to be, for example, about 450 nm. The film thickness of the above-described TEOS film is specified to be, for example, about 100 nm. The insulating film 40 and the laminated film 42 constitute an interlayer insulating film (insulating film) 44.

Opening portions 46a to 46c exposing the upper surfaces of the ring patterns 38a to 38c, respectively, and opening portions 48a to 48c connected to upper portions of the opening portions 46a to 46c, respectively, are disposed in the interlayer insulating film 44 in the peripheral region 4. The opening portion 46a and the opening portion 48a constitute a groove 50a. The opening portion 46b and the opening portion 48b constitute a groove 50b. The opening portion 46c and the opening portion 48c constitute a groove 50c. The grooves 50a to 50c are disposed in such a way as to surround the circuit region 2. The widths of the opening portions 48a to 48c are specified to be larger than the widths of the opening portions 46a to 46c. The widths of the opening portions 46a to 46c are specified to be, for example, about 0.10 μm. The widths of the opening portions 48a to 48c are specified to be, for example, about 2.0 μm.

A contact hole 46d reaching the wiring 38d and a groove 48d connected to the upper portion of the contact hole 46d are disposed in the interlayer insulating film 44 in the circuit region 2. The diameter of the contact hole 46d is specified to be, for example, about 0.13 μm. The width of the groove 48d is specified to be, for example, about 0.14 μm.

The widths of the opening portions 46a to 46c are specified to be relatively small similarly to the diameter of the contact hole 46d. In the circuit region 2, it is preferable that the diameter of the contact hole 46d is specified to be relatively small from the viewpoint of size reduction and achievement of a higher degree of integration. In the case where the diameter of the contact hole 46d is specified to be relatively small while the widths of the opening portions 46a to 46c are specified to be relatively large, etching rates are different significantly in formation of the opening portions 46a to 46c and the contact hole 46d at the same time, so that defective production may result. Consequently, in the present embodiment, the widths of the opening portions 46a to 46c are specified to be relatively small similarly to the diameter of the contact hole 46d.

Furthermore, the width of the groove 48d to bury a wiring 52e is specified to be relatively large. The widths of opening portions 48a to 48c, in which the upper portions of ring patterns 52a to 52c are buried, are also specified to be relatively large. Since the width of the groove 48d and the widths of the opening portions 48a to 48c are relatively large, it does not occur that etching rates are different significantly in formation of the groove 48d and the opening portions 48a to 48c. Therefore, no particular problems occur.

Incidentally, in the case where the widths of the lower portions of the ring patterns 52a to 52c are specified to be nearly equal to the widths of the ring patterns 38a to 38c serving as the layers thereunder, if misregistration or the like occurs, even the interlayer insulating film 34 may be etched, so that defective production may result. Furthermore, the contact areas between the ring patterns 52a to 52c and the ring patterns 38a to 38c are not ensured sufficiently and, thereby, the strength of the moisture-resistant rings 8a to 8c may be reduced. In the present embodiment, since the widths of the lower portions of the ring patterns 52a to 52c are sufficiently small relative to the widths of the ring patterns 38a to 38c, even when misregistration occurs, the interlayer insulating film 34 is prevented from being etched and defective production may be avoided.

a barrier metal film (not illustrated in the drawing) is disposed in the grooves 50a to 50c, in the contact hole 46d, and in the groove 48d. As for the barrier metal film, for example, a Ta film is used. The film thickness of the barrier metal film is specified to be, for example, about 25 nm.

Ring patterns 52a to 52c are buried in the grooves 50a to 50c provided with the barrier metal film. The ring patterns 52a to 52c are connected to the ring patterns 38a to 38c, respectively. The width of the upper portion of each of the ring patterns 52a to 52c is specified to be larger than the width of the lower portion.

A conductor plug 52d and the wiring 52e are disposed in the contact hole 46d and in the groove 48d provided with the barrier metal film. The conductor plug 52d and the wiring 52e are formed integrally.

The conductor plug 52d, the wiring 52e, and the ring patterns 52a to 52c are formed from the same electrically conductive film. Here, as for the material for the conductor plug 52d, the wiring 52e, and the ring patterns 52a to 52c, for example, Cu is used.

The conductor plug 52d and the wiring 52e are formed by a dual damascene method. The dual damascene method is a technology, in which a contact hole and a groove are formed integrally in an interlayer insulating film and a conductor plug and a wiring are buried integrally into the resulting contact hole and the groove. In the present embodiment, the ring patterns 52a to 52c are also formed at the same time with the conductor plug 52d and the wiring 52e by the dual damascene method.

An interlayer insulating film 58 including an insulating film 54 and a laminated film 56 is disposed on the interlayer insulating film 44, in which the ring patterns 52a to 52c, the conductor plug 52d, and the wiring 52e are buried. The insulating film 54 is similar to the above-described insulating film 40. The laminated film 56 is similar to the above-described laminated film 42.

Opening portions 60a to 60c exposing the upper surfaces of the ring patterns 52a to 52c, respectively, and opening portions 62a to 62c connected to upper portions of the opening portions 60a to 60c, respectively, are disposed in the interlayer insulating film 58 in the peripheral region 4. The opening portion 60a and the opening portion 62a constitute a groove 64a. The opening portion 60b and the opening portion 62b constitute a groove 64b. The opening portion 60c and the opening portion 62c constitute a groove 64c. The grooves 64a to 64c are formed in a manner similar to those of the above-described grooves 50a to 50c.

A contact hole 60d reaching the wiring 52e and a groove 62d connected to the upper portion of the contact hole 60d are disposed in the interlayer insulating film 58 in the circuit region 2. The contact hole 60d is formed in a manner similar to that of the above-described contact hole 46d. The groove 62d is formed in a manner similar to that of the above-described groove 48d.

A barrier metal film (not illustrated in the drawing) is disposed in the grooves 64a to 64c, in the contact hole 60d, and in the groove 62d, as in the grooves 50a to 50c, in the contact hole 46d, and in the groove 48d.

Ring patterns 66a to 66c similar to the above-described ring patterns 52a to 52c are buried in the grooves 64a to 64c provided with the barrier metal film. The ring patterns 66a to 66c are connected to the ring patterns 52a to 52c, respectively.

Furthermore, a conductor plug 66d similar to the above-described conductor plug 52d and a wiring 66e similar to the above-described wiring 52e are buried in the contact hole 60d and in the groove 62d provided with the barrier metal film.

An interlayer insulating film 72 including an insulating film 68 and a laminated film 70 is disposed on the interlayer insulating film 58, in which the ring patterns 66a to 66c, the conductor plug 66d, and the wiring 66e are buried. The insulating film 68 is similar to the above-described insulating film 40. The laminated film 70 is similar to the above-described laminated film 42.

Opening portions 74a to 74c exposing the upper surfaces of the ring patterns 66a to 66c, respectively, and opening portions 76a to 76c connected to upper portions of the opening portions 74a to 74c, respectively, are disposed in the interlayer insulating film 72 in the peripheral region 4. The opening portion 74a and the opening portion 76a constitute a groove 78a. The opening portion 74b and the opening portion 76b constitute a groove 78b. The opening portion 74c and the opening portion 76c constitute a groove 78c. The grooves 78a to 78c are formed in a manner similar to those of the above-described grooves 50a to 50c.

A contact hole 74d reaching the wiring 66e and a groove 76d connected to the upper portion of the contact hole 74d are disposed in the interlayer insulating film 72 in the circuit region 2. The contact hole 74d is formed in a manner similar to that of the above-described contact hole 46d. The groove 76d is formed in a manner similar to that of the above-described groove 48d.

A barrier metal film (not illustrated in the drawing) is disposed in the grooves 78a to 78c, in the contact hole 74d, and in the groove 76d, as in the above-described grooves 50a to 50c, in the contact hole 46d, and in the groove 48d.

Ring patterns 80a to 80c similar to the above-described ring patterns 52a to 52c are buried in the grooves 78a to 78c provided with the barrier metal film. The ring patterns 80a to 80c are connected to the ring patterns 66a to 66c, respectively.

Furthermore, a conductor plug 80d similar to the above-described conductor plug 52d and a wiring 80e similar to the above-described wiring 52e are buried in the contact hole 74d and in the groove 76d provided with the barrier metal film.

An interlayer insulating film 86 including an insulating film 82 and a laminated film 84 is disposed on the interlayer insulating film 72, in which the ring patterns 80a to 80c, the conductor plug 80d, and the wiring 80e are buried. The insulating film 82 is similar to the above-described insulating film 40. The laminated film 84 is similar to the above-described laminated film 42.

Opening portions 88a to 88c exposing the upper surfaces of the ring patterns 80a to 80c, respectively, and opening portions 90a to 90c connected to upper portions of the opening portions 88a to 88c, respectively, are disposed in the interlayer insulating film 86 in the peripheral region 4. The opening portion 88a and the opening portion 90a constitute a groove 92a. The opening portion 88b and the opening portion 90b constitute a groove 92b. The opening portion 88c and the opening portion 90c constitute a groove 92c. The grooves 92a to 92c are formed in a manner similar to those of the above-described grooves 50a to 50c.

A contact hole 88d reaching the wiring 80e and a groove 90d connected to the upper portion of the contact hole 88d are disposed in the interlayer insulating film 86 in the circuit region 2. The contact hole 88d is formed in a manner similar to that of the above-described contact hole 46d. The groove 90d is formed in a manner similar to that of the above-described groove 48d.

A barrier metal film (not illustrated in the drawing) is disposed in the grooves 92a to 92c, in the contact hole 88d, and in the groove 90d, as in the above-described grooves 50a to 50c, in the contact hole 46d, and in the groove 48d.

Ring patterns 94a to 94c similar to the above-described ring patterns 52a to 52c are buried in the grooves 92a to 92c provided with the barrier metal film. The ring patterns 94a to 94c are connected to the ring patterns 80a to 80c, respectively.

Furthermore, a conductor plug 94d similar to the above-described conductor plug 52d and a wiring 94e similar to the above-described wiring 52e are buried in the contact hole 88d and in the groove 90d provided with the barrier metal film.

The first layer metal wiring 38d, the second layer metal wiring 52e, the third layer metal wiring 66e, the fourth layer metal wiring 80e, and the fifth layer metal wiring 94e may be referred to as lower layer wirings. The pitch of such lower layer wirings may be specified to be, for example, about 0.28 μm.

An interlayer insulating film 100 including an insulating film (Cu diffusion-preventing film, etching stopper film) 96 and a laminated film 98 is disposed on the interlayer insulating film 86, in which the ring patterns 94a to 94c, the conductor plug 94d, and the wiring 94e are buried. As for the insulating film 96, for example, a SiC film (SiOC film) is used. As described above, the SiC film is used as the insulating film 96 for the purpose of preventing diffusion of Cu and, in addition, improving stress migration resistance. The film thickness of the insulating film 96 is specified to be, for example, about 70 nm. The laminated film 98 is formed by laminating, for example, a SiOC film and a TEOS film sequentially. The film thickness of the above-described SiOC film is specified to be, for example, about 920 nm. The film thickness of the above-described TEOS film is specified to be, for example, about 30 nm.

Opening portions 102a to 102c exposing the upper surfaces of the ring patterns 94a to 94c and opening portions 104a to 104c connected to upper portions of the opening portions 102a to 102c, respectively, are disposed in the interlayer insulating film 100 in the peripheral region 4. The opening portion 102a and the opening portion 104a constitute a groove 106a. The opening portion 102b and the opening portion 104b constitute a groove 106b. The opening portion 102c and the opening portion 104c constitute a groove 106c. The widths of the opening portions 102a to 102c are specified to be, for example, about 0.28 μm. The widths of the opening portions 104a to 104c are specified to be, for example, about 2.0 μm.

A contact hole 102d reaching the wiring 94e and a groove 104d connected to the upper portion of the contact hole 102d are disposed in the interlayer insulating film 100 in the circuit region 2. The diameter of the contact hole 102d is specified to be, for example, about 0.28 μm. The width of the groove 104d is specified to be, for example, about 0.28 μm.

A barrier metal film (not illustrated in the drawing) is disposed in the grooves 106a to 106c, in the contact hole 102d, and in the groove 104d. As for the barrier metal film, for example, a Ta film is used. The film thickness of the barrier metal film is specified to be, for example, about 20 nm.

Ring patterns 108a to 108c are buried in the grooves 106a to 106c provided with the barrier metal film. The ring patterns 108a to 108c are connected to the ring patterns 94a to 94c, respectively.

A conductor plug 108d and a wiring 108e are buried in the contact hole 102d and in the groove 104d provided with the barrier metal film. The conductor plug 108d and the wiring 108e are formed integrally.

The conductor plug 108d, the wiring 108e, and the ring patterns 108a to 108c are formed from the same electrically conductive film. Here, as for the material for the conductor plug 108d, the wiring 108e, and the ring patterns 108a to 108c, for example, Cu is used. The conductor plug 108d, the wiring 108e, and the ring patterns 108a to 108c are formed by the dual damascene method.

An interlayer insulating film 114 including an insulating film 110 and a laminated film 112 is disposed on the interlayer insulating film 100, in which the ring patterns 108a to 108c, the conductor plug 108d, and the wiring 108e are buried. The insulating film 110 is similar to the above-described insulating film 96. The laminated film 112 is similar to the above-described laminated film 98.

Opening portions 116a to 116c exposing the upper surfaces of the ring patterns 106a to 106c, respectively, and opening portions 118a to 118c connected to upper portions of the opening portions 116a to 116c, respectively, are disposed in the interlayer insulating film 114 in the peripheral region 4. The opening portion 116a and the opening portion 118a constitute a groove 120a. The opening portion 116b and the opening portion 118b constitute a groove 120b. The opening portion 116c and the opening portion 118c constitute a groove 120c. The grooves 120a to 120c are formed in a manner similar to those of the above-described grooves 106a to 106c.

A contact hole 116d reaching the wiring 108e and a groove 118d connected to the upper portion of the contact hole 116d are disposed in the interlayer insulating film 114 in the circuit region 2. The contact hole 116d is formed in a manner similar to that of the above-described contact hole 102d. The groove 118d is formed in a manner similar to that of the above-described groove 104d.

A barrier metal film (not illustrated in the drawing) is disposed in the grooves 120a to 120c, in the contact hole 116d, and in the groove 118d, as in the above-described grooves 106a to 106c, in the contact hole 102d, and in the groove 104d.

Ring patterns 122a to 122c similar to the above-described ring patterns 108a to 108c are buried in the grooves 118a to 118c provided with the barrier metal film. The ring patterns 122a to 122c are connected to the ring patterns 108a to 108c, respectively.

Furthermore, a conductor plug 122d similar to the above-described conductor plug 108d and a wiring 122e similar to the above-described wiring 108e are buried in the contact hole 116d and in the groove 118d provided with the barrier metal film.

The sixth layer metal wiring 108e and the seventh layer metal wiring 122e may be referred to as middle layer wirings. The pitch of such middle layer wirings may be specified to be, for example, about 0.56 μm.

An interlayer insulating film 128 including an insulating film (Cu diffusion-preventing film, etching stopper film) 124 and an insulating film 126 is disposed on the interlayer insulating film 114, in which the ring patterns 122a to 122c, the conductor plug 122d, and the wiring 122e are buried. As for the insulating film 124, for example, a SiC film (SiOC film) is used. The film thickness of the insulating film 124 is specified to be, for example, about 70 nm. The insulating film 126 is formed from, for example, a silicon oxide film. The film thickness of the insulating film 126 is specified to be, for example, about 1,470 nm.

Opening portions 130a to 130c exposing the upper surfaces of the ring patterns 122a to 122c and opening portions 132a to 132c connected to upper portions of the opening portions 130a to 130c, respectively, are disposed in the interlayer insulating film 128 in the peripheral region 4. The opening portion 130a and the opening portion 132a constitute a groove 134a. The opening portion 130b and the opening portion 132b constitute a groove 134b. The opening portion 130c and the opening portion 132c constitute a groove 134c. The widths of the opening portions 130a to 130c are specified to be, for example, about 0.42 μm. The widths of the opening portions 132a to 132c are specified to be, for example, about 2.0 μm.

A contact hole 130d reaching the wiring 122e and a groove 132d connected to the upper portion of the contact hole 130d are disposed in the interlayer insulating film 128 in the circuit region 2. The diameter of the contact hole 130d is specified to be, for example, about 0.42 μm. The width of the groove 132d is specified to be, for example, about 0.42 μm.

A barrier metal film (not illustrated in the drawing) is disposed in the grooves 134a to 134c, in the contact hole 130d, and in the groove 132d. As for the barrier metal film, for example, a Ta film is used. The film thickness of the barrier metal film is specified to be, for example, about 20 nm.

Ring patterns 136a to 136c are buried in the grooves 134a to 134c provided with the barrier metal film. The ring patterns 136a to 136c are connected to the ring patterns 122a to 122c, respectively.

A conductor plug 136d and a wiring 136e are buried in the contact hole 130d and in the groove 132d provided with the barrier metal film. The conductor plug 136d and the wiring 136e are formed integrally.

The conductor plug 136d, the wiring 136e, and the ring patterns 136a to 136c are formed from the same electrically conductive film. Here, as for the material for the conductor plug 136d, the wiring 136e, and the ring patterns 136a to 136c, for example, Cu is used. The conductor plug 136d, the wiring 136e, and the ring patterns 136a to 136c are formed by the dual damascene method.

An interlayer insulating film (insulating layer) 142 including an insulating film 138 and an insulating film 140 is disposed on the interlayer insulating film 128, in which the ring patterns 136a to 136c, the conductor plug 136d, and the wiring 136e are buried. The insulating film 138 is similar to the above-described insulating film 124. The insulating film 140 is similar to the above-described laminated film 126.

Opening portions 144a to 144c exposing the upper surfaces of the ring patterns 136a to 136c, respectively, and opening portions 146a to 146c connected to upper portions of the opening portions 144a to 144c, respectively, are disposed in the interlayer insulating film 142 in the peripheral region 4. The widths of the opening portions 144a to 144c are specified to be, for example, about 0.42 μm. The widths of the opening portions 146a to 146c are specified to be, for example, about 2.0 μm. The opening portion 144a and the opening portion 146a constitute a groove 148a. The opening portion 144b and the opening portion 146b constitute a groove 148b. The opening portion 144c and the opening portion 146c constitute a groove 148c. The grooves 148a to 148c are formed in a manner similar to those of the above-described grooves 134a to 134c.

A contact hole 144d reaching the wiring 136e and a groove 146d connected to the upper portion of the contact hole 144d are disposed in the interlayer insulating film 142 in the circuit region 2. The contact hole 144d is formed in a manner similar to that of the above-described contact hole 130d. The groove 146d is formed in a manner similar to that of the above-described groove 132d.

A barrier metal film (not illustrated in the drawing) is disposed in the grooves 148a to 148c, in the contact hole 144d, and in the groove 146d, as in the above-described grooves 134a to 134c, in the contact hole 130d, and in the groove 132d.

Ring patterns 150a to 150c similar to the above-described ring patterns 136a to 136c are buried in the grooves 148a to 148c provided with the barrier metal film. The ring patterns 150a to 150c are disposed in such a way as to surround the circuit region 2. The ring patterns 150a to 150c are connected to the ring patterns 136a to 136c, respectively. The widths w1 (refer to FIG. 5) of the upper portion of the ring patterns 150a to 150c, that is, portions buried in the opening portions 146a to 146c of the ring patterns 150a to 150c, are specified to be, for example, about 2.0 μm.

Furthermore, a conductor plug 150d similar to the above-described conductor plug 130d and a wiring 150e similar to the above-described wiring 136e are buried in the contact hole 144d and the groove 146d provided with the barrier metal films. In a manner similar to that described above, the conductor plug 150d, the wiring 150e, and the ring patterns 150a to 150c are formed by the dual damascene method.

The eighth layer metal wiring 136e and the ninth layer metal wiring 150e may be referred to as upper layer wirings. The pitch of such upper layer wirings may be specified to be, for example, about 0.84 μm.

An interlayer insulating film (insulating layer) 156 including an insulating film (Cu diffusion-preventing film, etching stopper film) 152 and an insulating film 154 is disposed on the interlayer insulating film 142, in which the ring patterns 150a to 150c, the conductor plug 150d, and the wiring 150e are buried. As for the insulating film 152, for example, a SiC film (SiOC film) is used. The film thickness of the insulating film 152 is specified to be, for example, about 70 nm. The insulating film 154 is formed from, for example, a silicon oxide film. The film thickness of the insulating film 154 is specified to be, for example, about 1,400 nm.

In the present embodiment, the SiC film (SiOC film) is used as the material for the insulating film 152 in order to obtain sufficient stress migration resistance. In the case where a SiCN film or a SiN film is used as the material for the insulating film 152, the adhesion to the interlayer insulating film 142 serving as a substrate becomes better, but sufficient stress migration resistance is not obtained sometimes. The adhesion of the SIC film to the interlayer insulating film 142 serving as a substrate is poorer than that of the SiCN film or the SiN film. However, an improvement of the stress migration resistance is facilitated. Therefore, in the present embodiment, the SiC film is used as the insulating film 152.

Grooves 158a to 158c exposing the upper surfaces of the ring patterns 150a to 150c, respectively, are disposed in the interlayer insulating film 156 in the peripheral region 4. The widths of the grooves 158a to 158c are specified to be, for example, about 0.4 μm. The grooves 158a to 158c are disposed in such a way as to surround the circuit region 2.

A plurality of contact holes 158d reaching the wiring 150e are disposed in the interlayer insulating film 156 in the circuit region 2. The diameter of the contact holes 158d are specified to be, for example, about 0.5 μm.

A barrier metal film (not illustrated in the drawing) is disposed in the grooves 158a to 158c and in the contact hole 158d. As for the barrier metal film, for example, a TiN film is used. The film thickness of the above-described TiN film is specified to be, for example, about 50 nm.

Ring patterns 160a to 160c are buried in the grooves 158a to 158c provided with the barrier metal film. The ring patterns 160a to 160c are disposed in such a way as to surround the circuit region 2. The ring patterns 160a to 160c are connected to the ring patterns 150a to 150c, respectively. The widths w2 (refer to FIG. 5) of the ring patterns 160a to 160c are specified to be, for example, about 0.4 μm.

A conductor plug 160d is buried in the contact hole 158d provided with the barrier metal film. The conductor plug 160d is connected to the wiring 150e.

As for the material for the conductor plug 160d, for example, tungsten is used. The reason for the use of tungsten as the material for the conductor plug 160d is that a tungsten film may be formed in a relatively fine contact hole. Furthermore, in the case where Cu is used as the material for the conductor plug 160d, Cu may be corroded in etching of an aluminum film and the like in a downstream step, and poor contact may result. For such reasons, tungsten rather than Cu is used as the material for the conductor plug 160d.

The ring patterns 160a to 160c and the conductor plug 160d are formed from the same electrically conductive film at the same time. Therefore, in the present embodiment, for example, tungsten is also used as the material for the ring patterns 160a to 160c.

Ring patterns 162a to 162c are disposed on the interlayer insulating film 156 in the peripheral region 4. The ring patterns 162a to 162c are disposed in such a way as to surround the circuit region 2. The ring patterns 162a to 162c are connected to the ring patterns 160a to 160c, respectively. The ring patterns 162a to 162c are formed from a barrier metal film (not illustrated in the drawing) and a metal film (not illustrated in the drawing) disposed on the barrier metal film. As for such a barrier metal film, for example, a laminated film of a Ti film and a TiN film is used. The film thickness of the above-described Ti film is specified to be, for example, about 60 nm. The film thickness of the above-described TiN film is specified to be, for example, about 30 nm. As for the above-described metal film, for example, a laminated film of an aluminum film and a TiN film is used. The film thickness of the above-described aluminum film is specified to be, for example, about 1,000 nm. The film thickness of the above-described TiN film is specified to be, for example, about 50 nm. The widths of the ring patterns 162a to 162c are specified to be larger than the widths of the ring patterns 150a to 150c buried in the interlayer insulating film 142. Specifically, the widths w3 (refer to FIG. 5) of the ring patterns 162a to 162c are specified to be, for example, about 3.0 μm. Both side portions along the longitudinal direction of the ring patterns 162a to 162c are located in such a way as to protrude toward the outside by d1 from both side portions along the longitudinal direction of the ring patterns 150a to 150c (refer to FIG. 5). The distance d1 is specified to be, for example, about 0.5 μm.

In this regard, the ring patterns 162a to 162c are disposed on the ring patterns 160a to 160c because of the following reasons. That is, in the circuit region 2, an electrode pad 162d formed from the same electrically conductive film as that for the ring patterns 162a to 162c is disposed, as described later. The electrode pad 162d is formed by forming a photoresist film on the electrically conductive film, and etching the electrically conductive film while the photoresist film is used as a mask. In the case where the ring patterns 162a to 162c are not disposed on the ring patterns 160a to 160c, when the electrode pad 162d is formed by etching the electrically conductive film, even the ring patterns 160a to 160c are etched. If even the ring patterns 160a to 160c are etched, it becomes difficult to ensure sufficient moisture resistance. For these reasons, in the present embodiment, the ring patterns 162a to 162c are disposed on the ring patterns 160a to 160c.

Furthermore, the ring patterns 162a to 162c are not integrated and the ring patterns 162a to 162c are isolated from each other for the following reason. That is, in the case where the ring patterns 162a to 162c are formed integrally, when cracking occurs in a part of the ring pattern, moisture transfers along the crack, and it may become difficult to ensure the moisture resistance. In the case where the ring patterns 162a to 162c are disposed while being isolated from each other, even when cracking occurs in any one of the ring patterns 162a to 162c, cracking is not propagated to other ring patterns 162a to 162c. Consequently, the moisture resistance may be ensured reliably. For this reason, in the present embodiment, the ring patterns 162a to 162c are isolated from each other.

The moisture-resistant ring 8a is formed from the ring patterns 28a, 38a, 52a, 66a, 80a, 94a, 108a, 122a, 136a, 150a, 160a, and 162a. The moisture-resistant ring 8b is formed from the ring patterns 28b, 38b, 52b, 66b, 80b, 94b, 108b, 122b, 136b, 150b, 160b, and 162b. The moisture-resistant ring 8c is formed from the ring patterns 28c, 38c, 52c, 66c, 80c, 94c, 108c, 122c, 136c, 150c, 160c, and 162c.

As illustrated in FIG. 1, the two side portions along a longitudinal direction of the ring patterns 162a to 162c, that is, the two side portions of the ring patterns 162a to 162c along the direction perpendicular to the drawing illustrated in FIG. 1, do not overlap the ring patterns 150a to 150c two-dimensionally. That is, the two side portions of the ring patterns 162a to 162c along the direction perpendicular to the drawing illustrated in FIG. 5 do not overlap the ring patterns 150a to 150c two-dimensionally. Put another way, the ring patterns 150a to 150c are not located in the region just below the two side portions along the longitudinal direction of the ring patterns 162a to 162c. Put another way, the two side portions along the longitudinal direction of the ring patterns 162a to 162c are located outside the region just above the ring patterns 150a to 150c.

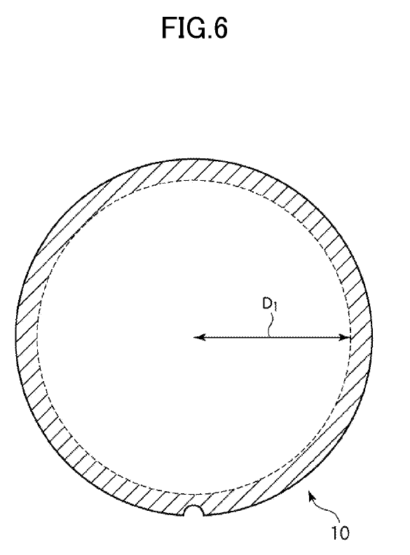

FIG. 6 is a plan view illustrating a semiconductor wafer before dicing is conducted. In the semiconductor wafer 10, the region excluding the peripheral portion, that is, in the region having a radius of D1, the phenomenon, in which the interlayer insulating film 156 exposed at the peripheries of the ring patterns 162a to 162c is removed excessively, does not occur easily. In the case where the semiconductor wafer 10 has a diameter of 300 mm, the radius D1 of the region, in which the above-described phenomenon does not occur easily, is about 145 mm, for example. On the other hand, in the region of the peripheral portion in the semiconductor 10, that is, in the hatched region in FIG. 6, the interlayer insulating film 156 exposed at the peripheries of the ring patterns 162a to 162c may be removed excessively.

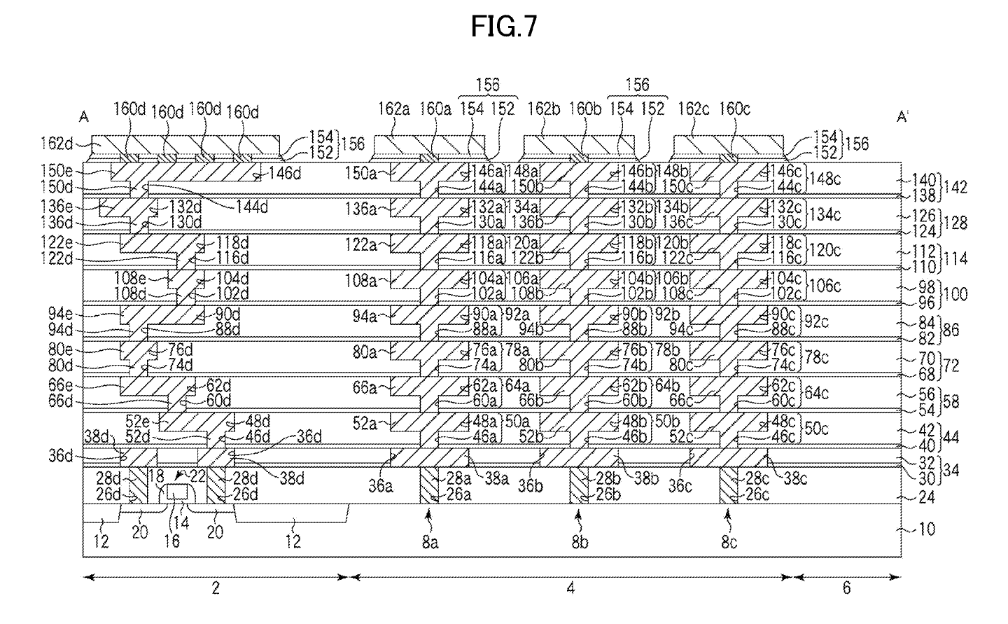

FIG. 7 is a sectional view illustrating the case where the interlayer insulating film 156 exposed at the peripheries of the ring patterns 162a to 162c has been removed excessively. As described above, such a phenomenon occurs easily in the peripheral portion of the semiconductor wafer 10. In the case where the interlayer insulating film 154 is etched to a relatively large extent through polishing for flattening the interlayer insulating film 156, polishing in burying of the ring patterns 160a to 160c, etching of the ring patterns 162a to 162c, or the like, the status illustrated in FIG. 7 may result.

The polishing for flattening the interlayer insulating film 156 refers to polishing conducted by, for example, a CMP method after the interlayer insulating film 156 is formed. In the case where the widths of the upper portions of the ring patterns 150a to 150c are relatively large, dishing of the surface of the ring patterns 150a to 150c is relatively large, so that the polishing for flattening is conducted after the interlayer insulating film 156 is formed. In the peripheral portion of the semiconductor wafer 10, the surface of the interlayer insulating film 156 may be removed through polishing to a large extent as compared with the central portion of the semiconductor wafer 10.

The polishing in burying of the ring patterns 160a to 160c refers to polishing conducted by, for example, a CMP method after the electrically conductive film is formed in the grooves 158a to 158c and on the interlayer insulating film 156. The ring patterns 160a to 160c are thereby buried into the grooves 158a to 158c. In the peripheral portion of the semiconductor wafer 10, the surface of the interlayer insulating film 156 may be removed through polishing to a large extent as compared with the central portion of the semiconductor wafer 10. Furthermore, the surface of the interlayer insulating film 156 is removed through polishing by over polishing conducted at this time.

The etching of the ring patterns 162a to 162c refers to etching conducted while a photoresist film is used as a mask after the electrically conductive film is formed and the photoresist film is formed on the resulting electrically conductive film. Since over etching is conducted to some extent, the interlayer insulating film 156 is removed at this time as well.

In the present embodiment, the two side portions along the longitudinal direction of the ring patterns 162a to 162c do not overlap the ring patterns 150a to 150c two-dimensionally. That is, in the present embodiment, the two side portions along the longitudinal direction of the ring patterns 162a to 162c are located outside the region just above the ring patterns 150a to 150c. Consequently, in the present embodiment, even when the interlayer insulating film 154 is removed excessively through polishing, etching, or the like, as illustrated in FIG. 7, the condition, in which at least a part of the interlayer insulating film 156 of the portions just below the ring patterns 162a to 162c is in contact with the interlayer insulating film 142, is maintained. Since the adhesion between the interlayer insulating film 156 and the interlayer insulating film 142 is relatively good, the interlayer insulating film 156 in contact with the interlayer insulating film 142 is not peeled off the interlayer insulating film 142. Consequently, according to the present embodiment, even when the interlayer insulating film 156 exposed at the peripheries of the ring patterns 162a to 162c is removed excessively through polishing, etching, or the like, peeling of the ring patterns 162a to 162c may be prevented.

The electrode pad 162d is disposed on the interlayer insulating film 156 in the circuit region 2. The electrode pad 162d is connected to the conductor plug 160d. The electrode pad 162d is formed from the same electrically conductive film as that for the ring patterns 162a to 162c. That is, the electrode pad 162d is formed from the barrier metal film (not illustrated in the drawing) and the metal film (not illustrated in the drawing) disposed on the barrier metal film. As described above, for example, the laminated film of the Ti film and the TiN film is used as the barrier metal film. The film thickness of the above-described Ti film is specified to be, for example, about 60 nm. The film thickness of the above-described TiN film is specified to be, for example, about 30 nm. As for the above-described metal film, for example, the laminated film of the aluminum film and the TiN film is used, as described above. The film thickness of the above-described aluminum film is specified to be, for example, about 1,000 nm. The film thickness of the above-described TiN film is specified to be, for example, about 50 nm.

A protective film 168 formed by laminating, for example, a silicon oxide film 164 and a silicon nitride film 166 sequentially is disposed on the interlayer insulating film 156 provided with the ring patterns 162a to 162c and the electrode pad 162d. The film thickness of the silicon oxide film 164 is specified to be, for example, about 1,400 nm. Te film thickness of the silicon nitride film 166 is specified to be, for example, about 500 nm.

An opening portion 170 exposing the upper surface of the electrode pad 162d is disposed in the protective film 168. The above-described opening portion 170 makes it possible to connect the electrode pad 162d to the outside.

A protective film 172 is disposed on the protective film 168 provided with the opening portion 170. As for the material for the protective film 172, for example, photosensitive polyimide is used. The film thickness of the protective film 172 is specified to be, for example, about 2.0 nm.

An opening portion 174 exposing the upper surface of the electrode pad 162d is disposed in the protective film 172. The above-described opening portion 174 makes it possible to connect the electrode pad 162d to the outside.

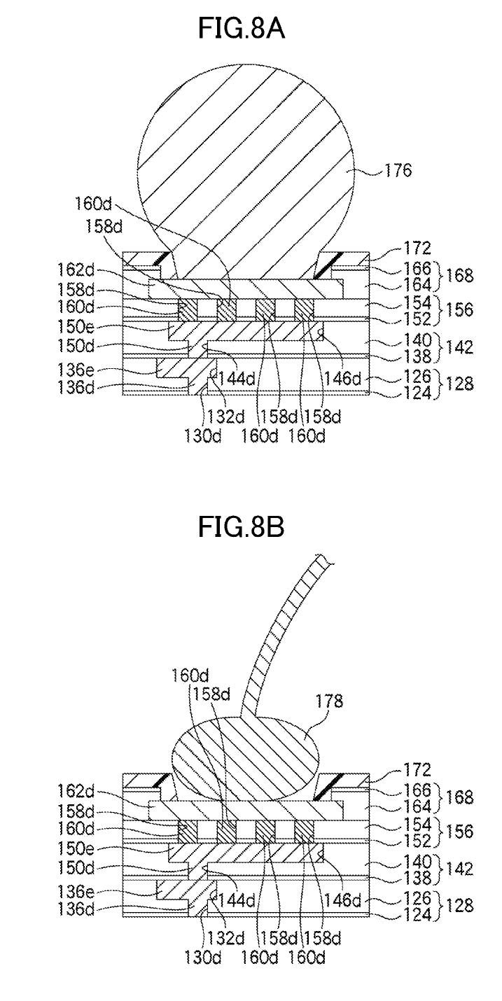

FIGS. 8A and 8B are sectional views illustrating the states in which a solder bump or a bonding wire is connected to the semiconductor device according to the present embodiment.

As illustrated in FIG. 8A, a solder bump 176 may be disposed on the electrode pad 162d. Alternatively, as illustrated in FIG. 8B, a bonding wire 178 may be connected to the electrode pad 162d.

In this manner, the semiconductor device according to the present embodiment is formed.

As described above, according to the present embodiment, the two side portions along the longitudinal direction of the ring patterns 162a to 162c do not overlap the ring patterns 150a to 150c two-dimensionally. That is, in the present embodiment, the two side portions along the longitudinal direction of the ring patterns 162a to 162c are located outside the regions just above the ring patterns 150a to 150c. Consequently, in the present embodiment, even when the interlayer insulating film 154 is removed excessively through polishing, etching, or the like, the condition, in which at least a part of the interlayer insulating film 156 of the portions just below the ring patterns 162a to 162c is in contact with the interlayer insulating film 142, is maintained. Since the adhesion between the interlayer insulating film 156 and the interlayer insulating film 142 is relatively good, the interlayer insulating film 156 in contact with the interlayer insulating film 142 is not peeled off the interlayer insulating film 142. Consequently, according to the present embodiment, even when the interlayer insulating film 156 exposed at the peripheries of the ring patterns 162a to 162c is removed excessively through polishing, etching, or the like, peeling of the ring patterns 162a to 162c may be prevented. Moreover, according to the present embodiment, since the plurality of moisture-resistant rings 8a to 8c are disposed, intrusion of moisture into the circuit region 2 is prevented reliably. Furthermore, since the ring patterns 162a to 162c are isolated from each other, even when cracking occurs in any one of the ring patterns 162a to 162c, cracking is not propagated. Consequently, intrusion of moisture into the circuit region 2 is prevented reliably.

(Method for Manufacturing Semiconductor Device)

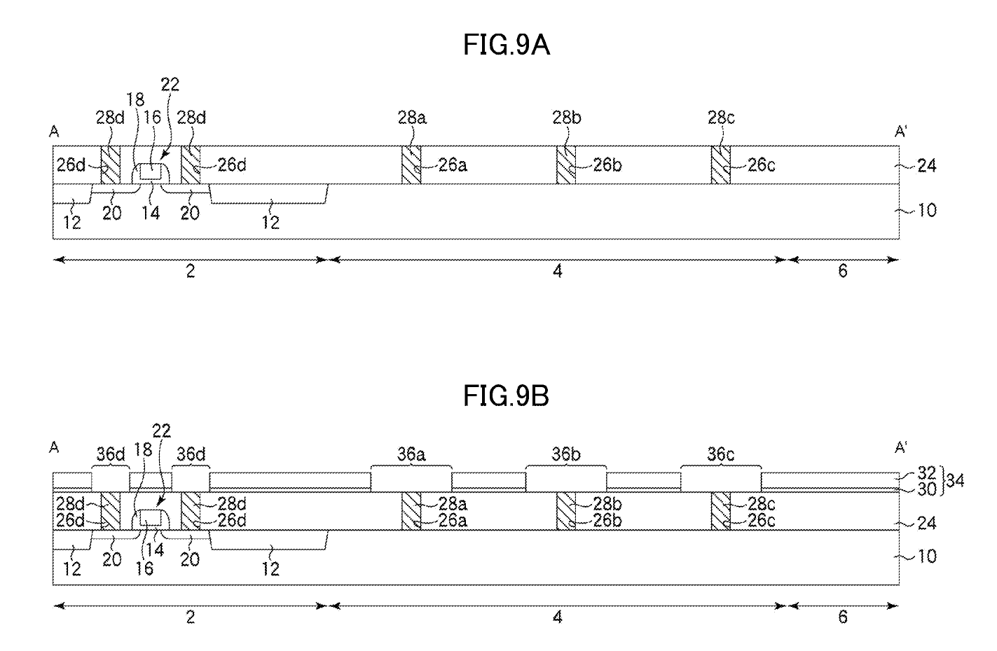

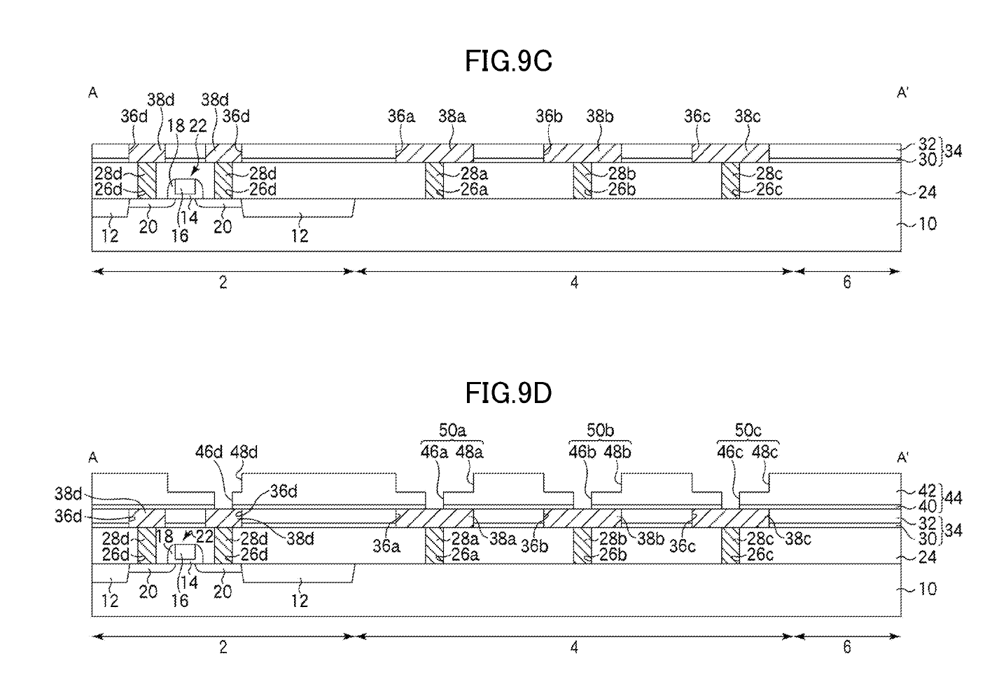

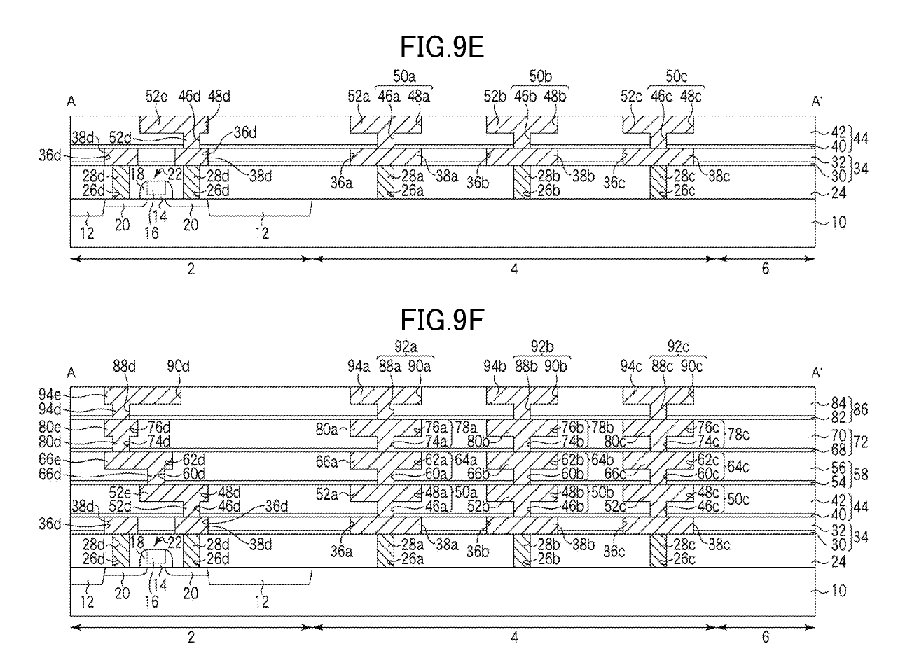

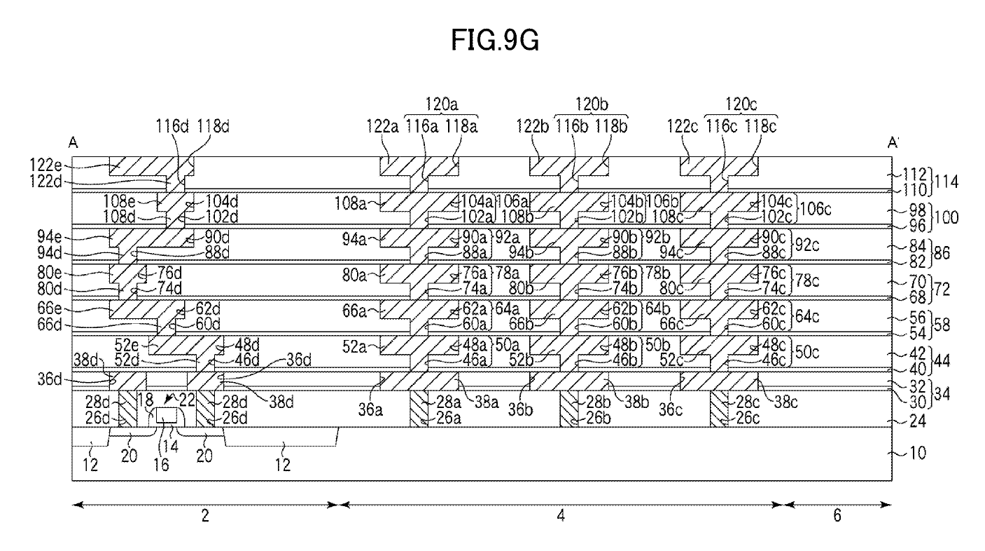

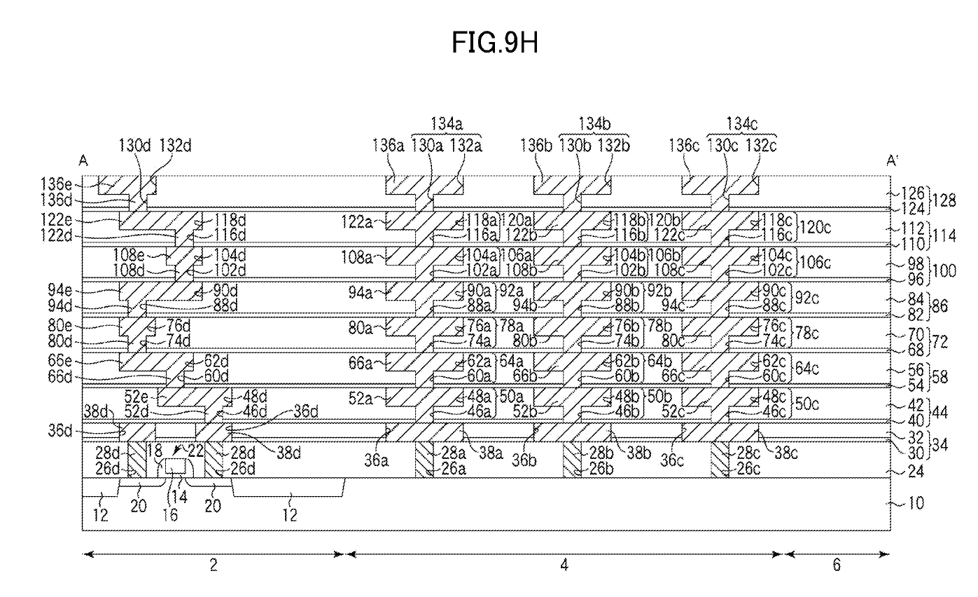

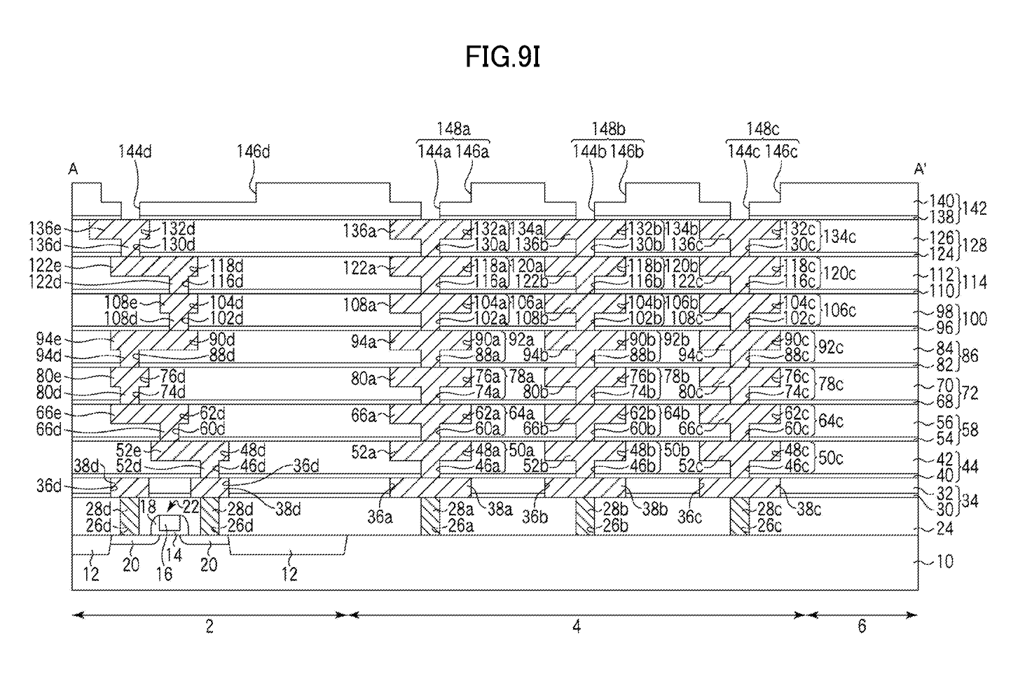

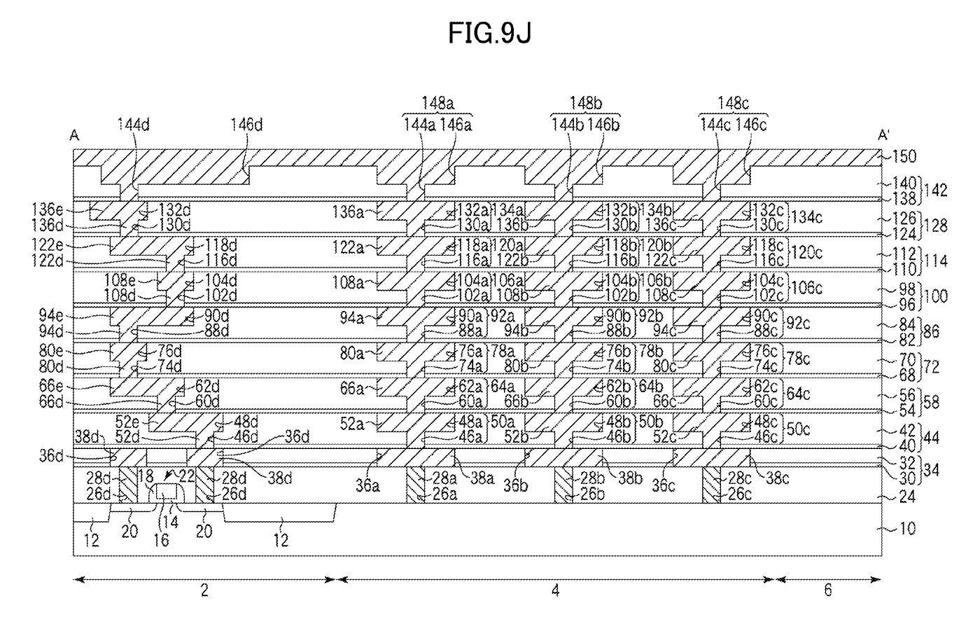

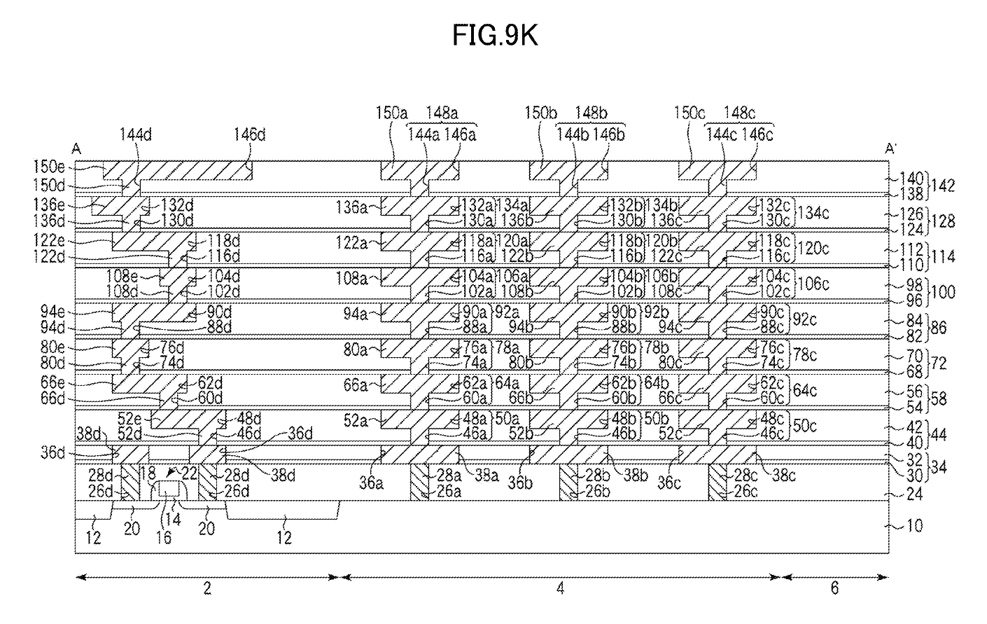

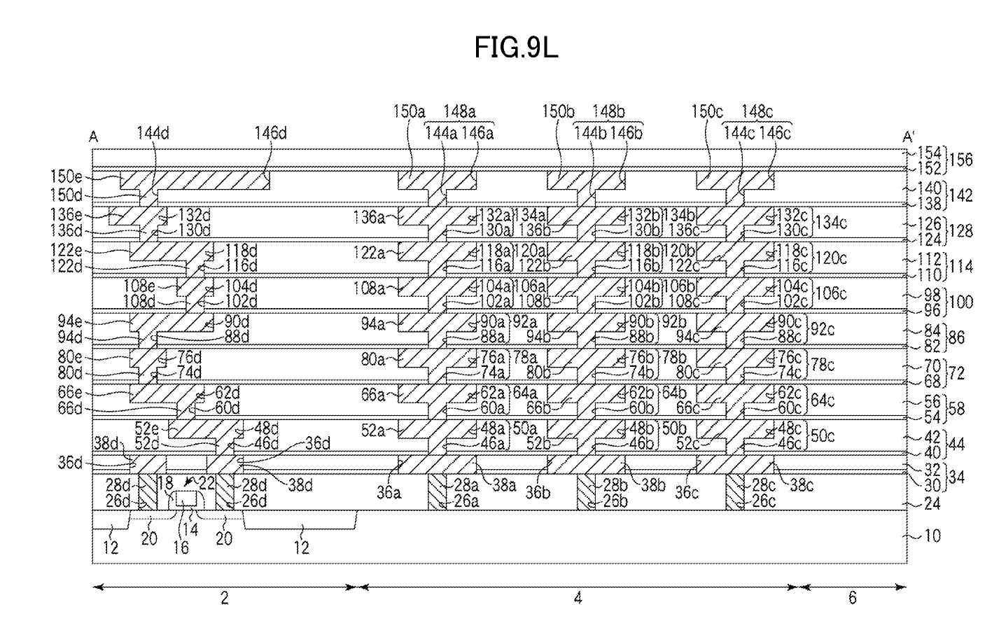

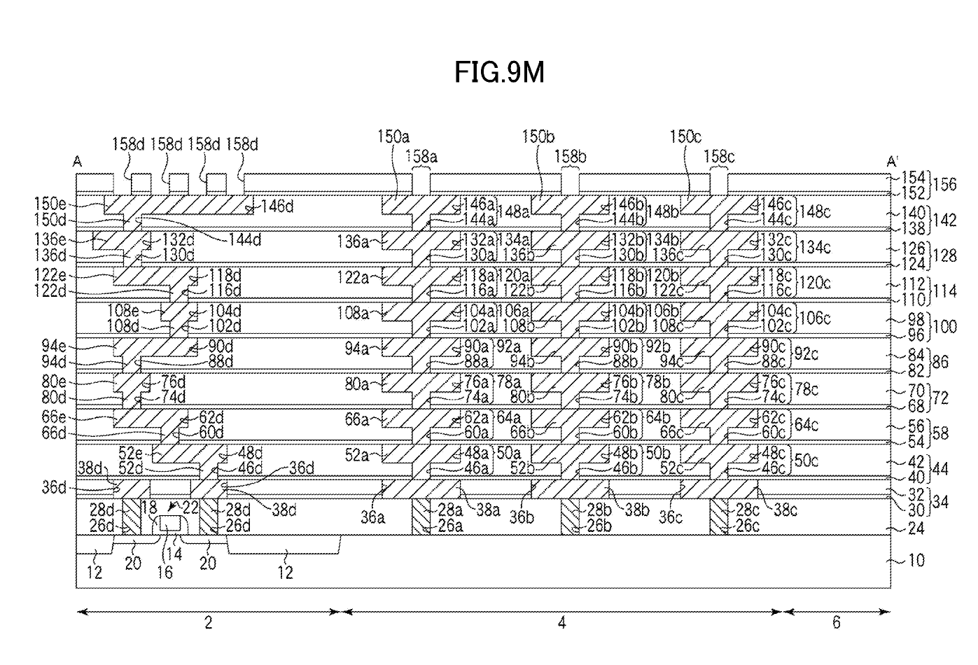

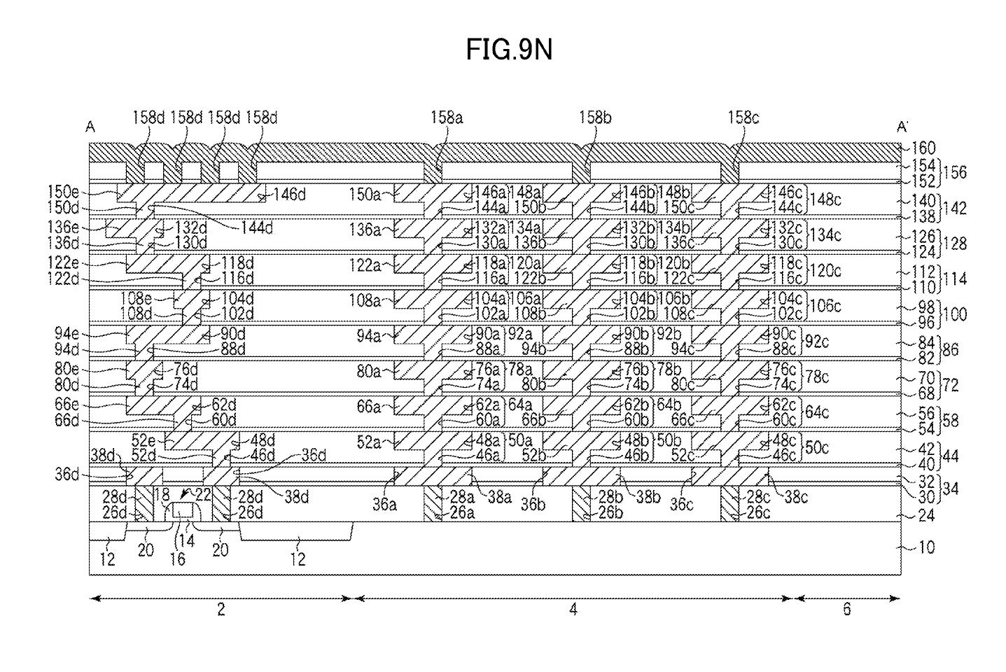

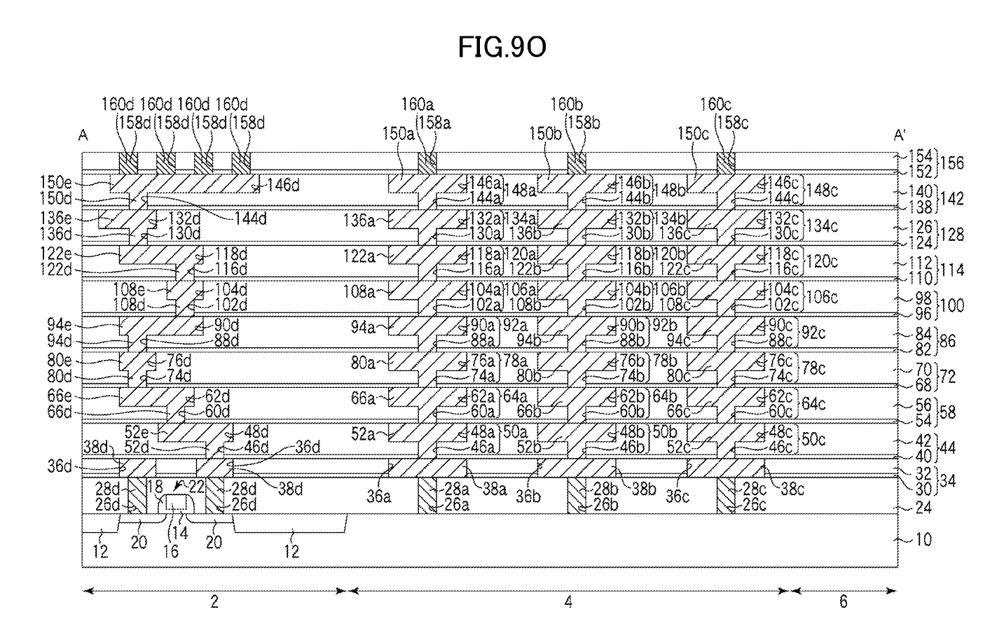

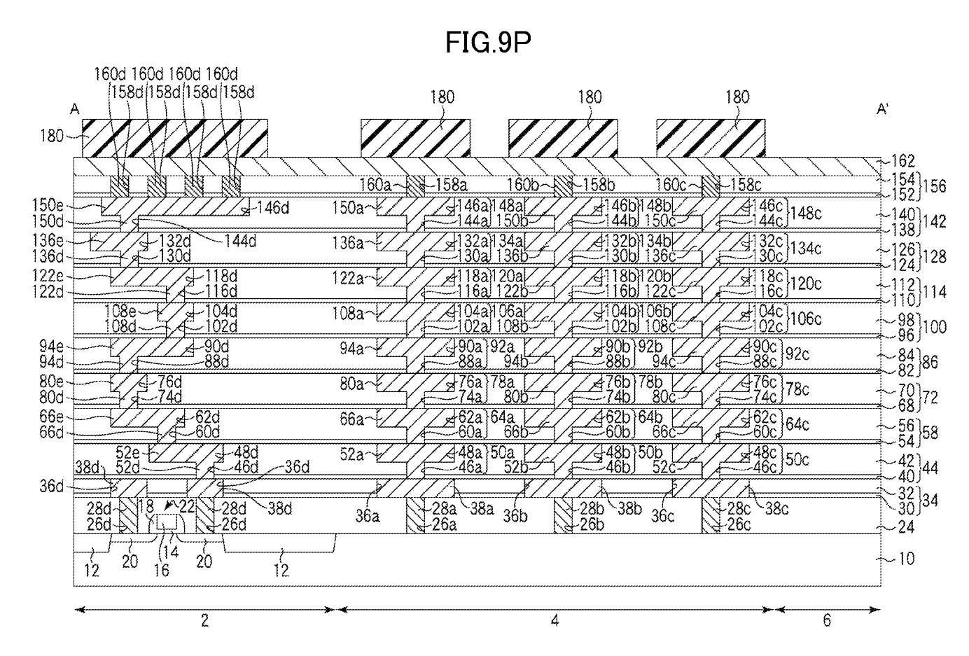

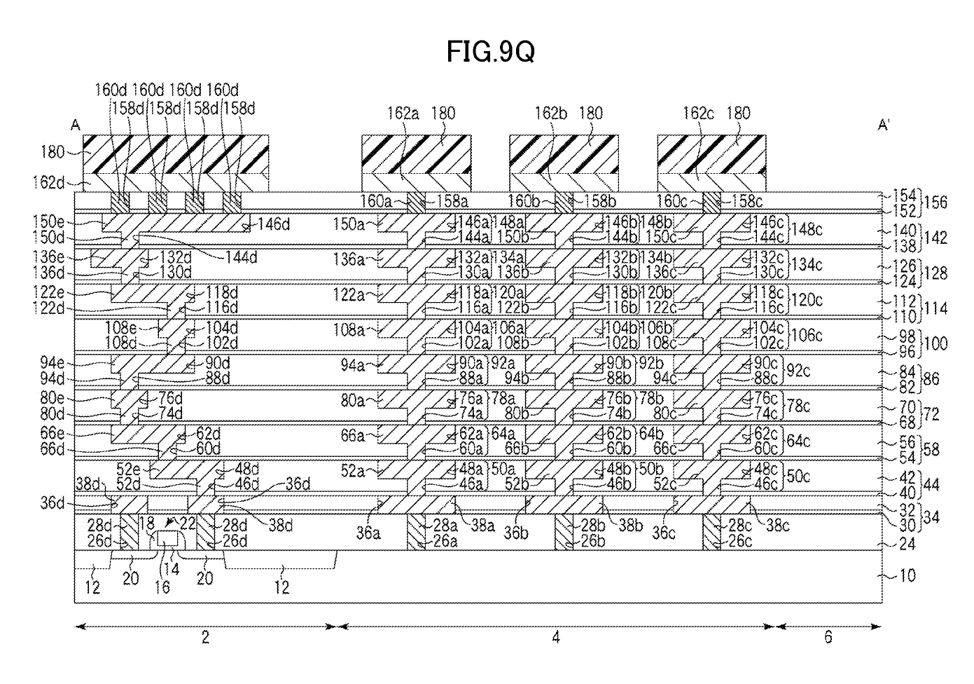

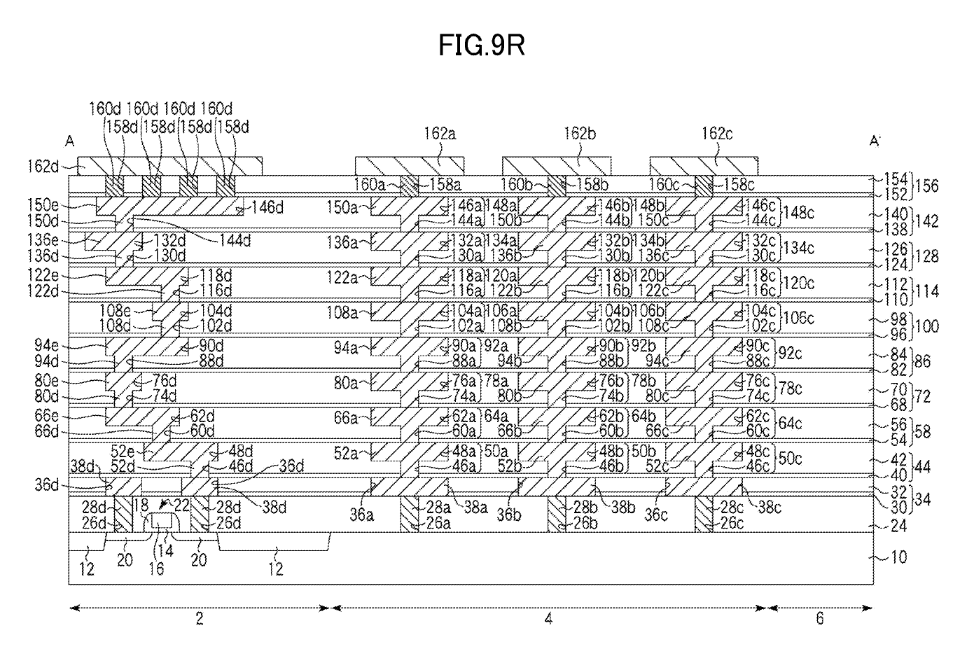

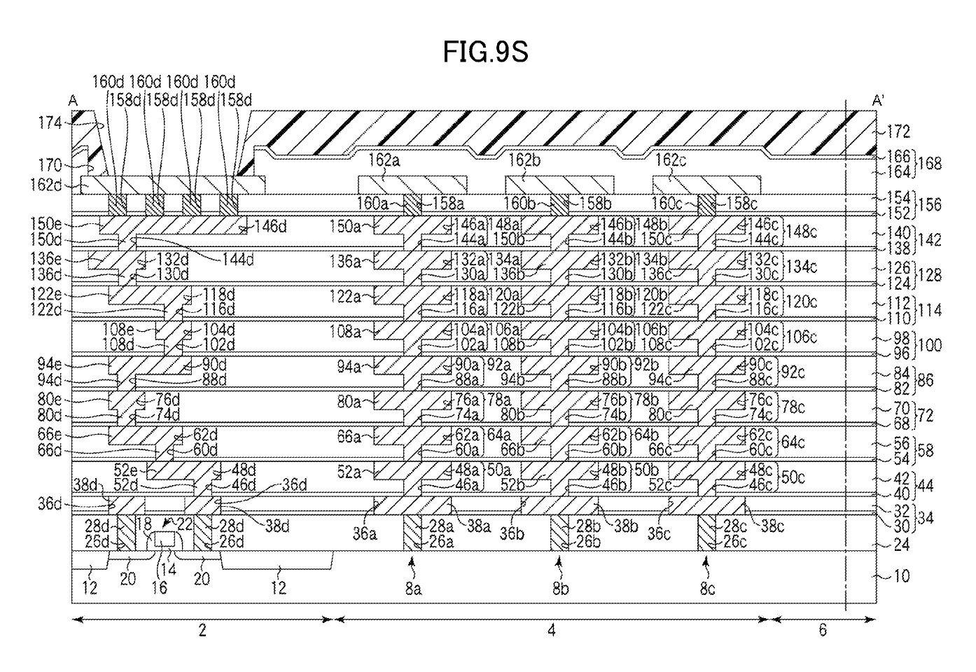

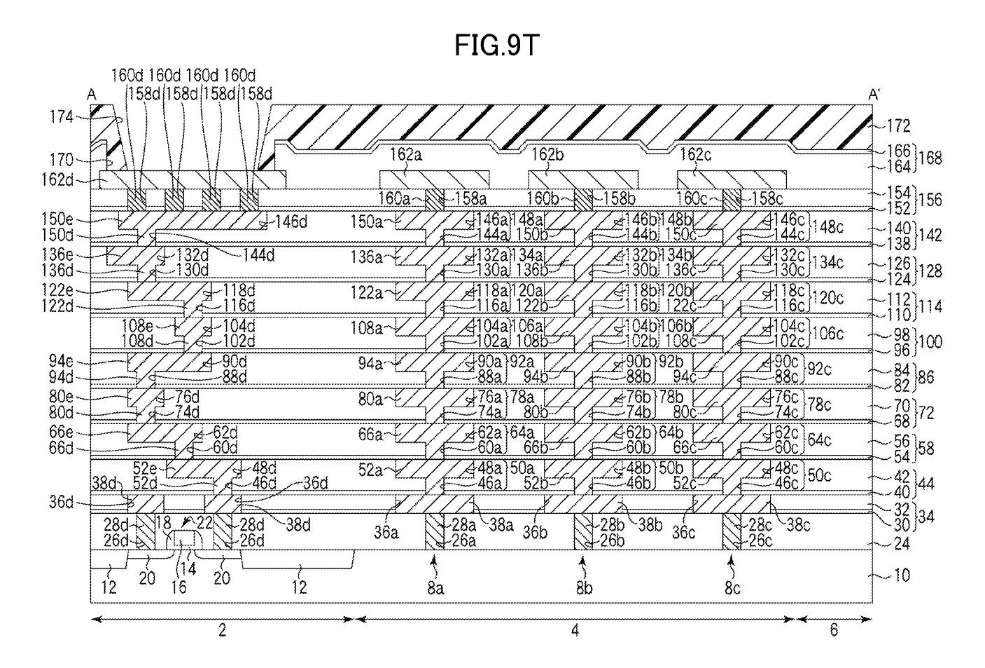

Next, a method for manufacturing the semiconductor device according to the present embodiment will be described with reference to FIG. 9A to FIG. 11. FIGS. 9A to 9T are sectional views illustrating steps of the method for manufacturing the conductor device according to the present embodiment.

Initially, as illustrated in FIG. 9A, the element isolation regions 12 to determine the element region are formed on the semiconductor substrate 10. As for the semiconductor substrate 10, for example, a silicon substrate is used. The element isolation regions 12 is formed by, for example, a shallow trench isolation (STI) method. As for the material for the element isolation region 12, for example, silicon dioxide is used.

Subsequently, the gate electrode 16 is formed on the semiconductor substrate 10 in the element region with the gate insulating film 14 therebetween. The gate electrode 16 is formed by forming, for example, a polysilicon film, and patterning the resulting polysilicon film.

A side wall insulating film 18 is formed on the side wall portion of the gate electrode 16. The side wall insulating film 18 is formed by forming, for example, a silicon oxide film, and conducting anisotropic etching of the resulting silicon oxide film.

For example, source/drain diffusion layers 20 are disposed in the semiconductor substrate 10 on both sides of the gate electrode 16 provided with the side wall insulating film 18 by, for example, an ion implantation method. In this manner, the transistor 22 including the gate electrode 16 and the source/drain diffusion layers 20 is formed.

A silicon nitride film (not illustrated in the drawing) is formed all over the surface by a chemical vapor deposition (CVD) method. The film thickness of the silicon nitride film is specified to be, for example, about 600 nm.

A phospho-silicate-glass (PSG) film is formed all over the surface by, for example, the CVD method. The film thickness of the PSG film is specified to be, for example, about 720 nm. The above-described silicon nitride film and the PSG film constitute the interlayer insulating film 24.

The grooves 26a to 26c reaching the semiconductor substrate 10 are formed in the interlayer insulating film 24 in the peripheral region 4 by using photolithography and, in addition, the contact holes 26d reaching the source/drain diffusion layers 20 are formed in the interlayer insulating film 24 in the circuit region 2. The widths of the grooves 26a to 26c are specified to be, for example, about 0.1 μm. The grooves 26a to 26c are formed in such a way as to surround the circuit region 2, and the diameter of the contact hole 26d is specified to be, for example, about 0.12 μm.

A Ti film (not illustrated in the drawing) and a TiN film (not illustrated in the drawing) are laminated all over the surface sequentially by, for example, the CVD method. The film thickness of the above-described Ti film is specified to be, for example, about 10 nm. The film thickness of the above-described TiN film is specified to be, for example, about 10 nm. The Ti film and the TiN film constitute a barrier metal film (not illustrated in the drawing). The barrier metal film is also formed in the grooves 26a to 26c and in the contact holes 26d.

A tungsten film is formed all over the surface by, for example, the CVD method. Here, the tungsten film is used because it is possible to conduct burying into fine grooves 26a to 26c and the contact holes 26d. The film thickness of the aluminum film is specified to be, for example, about 200 nm.

The tungsten film and the barrier metal film are polished by, for example, the CVD method until the surface of the interlayer insulating film 24 is exposed. In this manner, the tungsten ring patterns 28a to 28c are buried in the grooves 26a to 26c, respectively, provided with the barrier metal film. The ring patterns 28a to 28c serve as a part of the moisture-resistant rings 8a to 8c, respectively. The ring patterns 28a to 28c are formed in such a way as to surround the circuit region 2. The ring patterns 28a to 28c are connected to the semiconductor substrate 10. Furthermore, conductor plugs 28d are buried into the contact holes 26d provided with the barrier metal film.

The insulating film (etching stopper film) 30 is formed all over the surface by, for example, a plasma CVD method. As for the insulating film 30, for example, a SiC film (SiOC film) is formed. The film thickness of the insulating film 30 is specified to be, for example, about 30 nm.

Then, a SiOC film (not illustrated in the drawing) is formed all over the surface by, for example, the plasma CVD method. The film thickness of the SiOC film is specified to be, for example, about 130 nm.

A tetraethoxy silane (TEOS) film (not illustrated in the drawing) is formed all over the surface by, for example, the plasma CVD method. The film thickness of the TEOS film is specified to be, for example, about 100 nm. The SiOC film and the TEOS film constitute the laminated film 32. The insulating film 30 and the laminated film 32 constitute the interlayer insulating film 34.

The grooves 36a to 36c exposing the surfaces of the ring patterns 28a to 28c are formed in the interlayer insulating film 34 in the peripheral region 4 by using the photolithography (refer to FIG. 9B). At this time, the grooves 36d, each exposing the upper surface of the conductor plug 28d, are also formed in the interlayer insulating film 34 in the circuit region 2. The grooves 36a to 36c are formed in such a way as to surround the circuit region 2. The widths of the grooves 36a to 36c are specified to be larger than the widths of the grooves 26a to 26c. The widths of the grooves 36a to 36c are specified to be, for example, about 2.0 μm. The widths of the grooves 36d are specified to be, for example, about 0.12 μm.

A barrier metal film (not illustrated in the drawing) is formed all over the surface by, for example, a sputtering method. As for the barrier metal film, for example, a Ta film is used. The film thickness of the barrier metal film is specified to be, for example, about 10 nm. The barrier metal film prevents diffusion of Cu used as a material for the ring patterns 38a to 38c and the wirings 38d. The barrier metal film is also formed in the grooves 36a to 36c and in the grooves 36d.

A seed layer (not illustrated in the drawing) is formed all over the surface by, for example, the sputtering method. As for the seed layer, for example, a Cu layer is formed. The film thickness of the seed layer is specified to be, for example, about 100 nm. The seed layer is also formed in the grooves 36a to 36c and in the grooves 36d.

Then, an electrically conductive film is formed all over the surface by an electrolytic plating method. As for the electrically conductive film, for example, a Cu film is formed. The reason for the use of Cu film as the electrically conductive film is that reduction in wiring resistance or the like is facilitated and an improvement in working speed of the semiconductor device is facilitated. The film thickness of the electrically conductive film is specified to be, for example, about 1.0 μm.

The electrically conductive film, the seed layer, and the barrier metal film are polished by, for example, the CMP method until the surface of the interlayer insulating film 34 is exposed. In this manner, the ring patterns 38a to 38c are buried in the grooves 36a to 36c provided with the barrier metal film (refer to FIG. 9C). The ring patterns 38a to 38c are formed in such a way as to surround the circuit region 2. The ring patterns 38a to 38c are connected to the ring patterns 28a to 28c, respectively. Furthermore, the wirings 38d are buried in the grooves 36d provided with the barrier metal film. The wirings 38d are connected to the conductor plugs 28d.

Then, the insulating film (Cu diffusion-preventing film, cap film) 40 is formed all over the surface by, for example, the plasma CVD method. As for the insulating film 40, for example, a SiC film (SiOC film) is formed. The film thickness of the insulating film 40 is specified to be, for example, about 55 nm. The SiC film is used as the material for the insulating film 40 because the SiC film may prevent diffusion of Cu and, in addition, facilitate an improvement in stress migration resistance.

A SiOC film (not illustrated in the drawing) is formed all over the surface by, for example, a plasma CVD method. The film thickness of the SiOC film is specified to be, for example, about 450 nm.

A TEOS film (not illustrated in the drawing) is formed all over the surface by, for example, the plasma CVD method. The film thickness of the TEOS film is specified to be, for example, about 100 nm. The SiOC film and the TEOS film constitute the laminated film 42. The insulating film 40 and the laminated film 42 constitute the interlayer insulating film 44.

A photoresist film (not illustrated in the drawing) is formed all over the surface by, for example, a spin coating method.

Opening portions (not illustrated in the drawing) for forming the opening portions 46a to 46c and an opening portion (not illustrated in the drawing) for forming the contact hole 46d are formed in the photoresist film by using photolithography.

The laminated film 42 is etched while the photoresist film is used as a mask. In this manner, the opening portions 46a to 46c and the contact hole 46d are formed in such a way as to reach the insulating film 40. Thereafter, the photoresist film is peeled.

A resin layer (not illustrated in the drawing) is formed all over the surface by, for example, a spin coating method. The resin layer is also buried into the opening portions 46a to 46c and in the contact hole 46d.

The resin layer is etched back to a predetermined depth by using plasma generated through the use of, for example, an O₂ gas. Consequently, the resin remains in at least a part of the opening portions 46a to 46c and in at least a part of the contact hole 46d.

Then, a photoresist film (not illustrated in the drawing) is formed all over the surface by, for example, a spin coating method.

Opening portions (not illustrated in the drawing) for forming the opening portions 48a to 48c and an opening portion (not illustrated in the drawing) for forming the groove 48d are formed in the photoresist film by using photolithography.

The interlayer insulating film 44 is etched to a predetermined depth while the photoresist film is used as a mask.

The photoresist film is peeled and, in addition, the resin in the opening portions 46a to 46c and in the contact hole 46d is removed by using plasma generated through the use of, for example, an O₂ gas and a CF₄ gas.

The insulating film 40 exposed at the opening portions 46a to 46c and at the contact hole 46d is removed through, for example, dry etching.

In this manner, the opening portions 46a to 46c exposing the upper surfaces of the ring patterns 38a to 38c, respectively, and opening portions 48a to 48c connected to upper portions of the opening portions 46a to 46c, respectively, are formed in the interlayer insulating film 44 in the peripheral region 4 (refer to FIG. 9D). The opening portion 46a and the opening portion 48a constitute the groove 50a. The opening portion 46b and the opening portion 48b constitute the groove 50b. The opening portion 46c and the opening portion 48c constitute the groove 50c. The grooves 50a to 50c are formed in such a way as to surround the circuit region 2. The widths of the opening portions 48a to 48c are specified to be larger than the widths of the opening portions 46a to 46c. The widths of the opening portions 46a to 46c are specified to be, for example, about 0.10 μm. The widths of the opening portions 48a to 48c are specified to be, for example, about 2.0 μm.

Furthermore, the contact hole 46d reaching the wiring 38d and the groove 48d connected to the upper portion of the contact hole 46d are formed in the interlayer insulating film 44 in the circuit region 2. The diameter of the contact hole 46d is specified to be, for example, about 0.13 μm. The width of the groove 48d is specified to be, for example, about 0.14 μm.

The widths of the opening portions 46a to 46c are specified to be relatively small similarly to the diameter of the contact hole 46d. In the circuit region 2, it is preferable that the diameter of the contact hole 46d is specified to be relatively small from the viewpoint of size reduction and achievement of a higher degree of integration. In the case where the diameter of the contact hole 46d is specified to be relatively small while the widths of the opening portions 46a to 46c are specified to be relatively large, etching rates are different significantly in formation of the opening portions 46a to 46c and the contact hole 46d at the same time, so that defective production may result. Consequently, in the present embodiment, the widths of the opening portions 46a to 46c are specified to be relatively small similarly to the diameter of the contact hole 46d.

Furthermore, the width of the groove 48d to bury the wiring 52e is specified to be relatively large. The widths of opening portions 48a to 48c, in which the upper portions of ring patterns 52a to 52c are buried, are also specified to be relatively large. Since the width of the groove 48d and the widths of the opening portions 48a to 48c are relatively large, it does not occur that etching rates are different significantly in formation of the groove 48d and the opening portions 48a to 48c. Therefore, no particular problems occur.

Incidentally, in the case where the widths of the lower portions of the ring patterns 52a to 52c are specified to be nearly equal to the widths of the ring patterns 38a to 38c serving as the layers thereunder, if misregistration or the like occurs, even the interlayer insulating film 34 is etched, so that defective production may result. In the present embodiment, since the widths of the lower portions of the ring patterns 52a to 52c are sufficiently small relative to the widths of the ring patterns 38a to 38c, even when misregistration occurs, the interlayer insulating film 34 is prevented from being etched and defective production may be avoided.

Then, a barrier metal film (not illustrated in the drawing) is formed all over the surface by, for example, a sputtering method. As for the barrier metal film, for example, a Ta film is formed. The film thickness of the barrier metal film is specified to be, for example, about 25 nm. The barrier metal film is also formed in the grooves 50a to 50c, in the contact hole 46d, and in the grooves 48d.

A seed layer (not illustrated in the drawing) is formed all over the surface by, for example, the sputtering method. As for the seed layer, for example, a Cu film is formed. The film thickness of the seed layer is specified to be, for example, about 100 nm.

An electrically conductive film is formed all over the surface by, for example, an electrolytic plating method. As for the electrically conductive film, for example, a Cu film is formed. The film thickness of the electrically conductive film is specified to be, for example, about 1.0 μm.

The electrically conductive film, the seed layer, and the barrier metal film are polished by, for example, the CMP method until the surface of the interlayer insulating film 44 is exposed. In this manner, the ring patterns 52a to 52c composed of Cu are formed in the grooves 50a to 50c provided with the barrier metal film (refer to FIG. 9E). The ring patterns 52a to 52c are connected to the ring patterns 38a to 38c, respectively. The width of the upper portion of each of the ring patterns 52a to 52c is specified to be larger than the width of the lower portion. Furthermore, the conductor plug 52d and the wiring 52e are formed by a dual damascene method in the contact hole 46d and in the groove 48d provided with the barrier metal film. The conductor plug 52d and the wiring 52e are formed integrally. The dual damascene method is a technology, in which a contact hole and a groove are formed integrally in an interlayer insulating film and a conductor plug and a wiring are buried integrally into the resulting contact hole and the groove. In the present embodiment, the ring patterns 52a to 52c are also formed at the same time with formation of the conductor plug 52d and the wiring 52e by the dual damascene method.

The interlayer insulating film 58 including the insulating film 54 and the laminated film 56 is formed all over the surface (refer to FIG. 9F). The insulating film 54 is formed in a manner similar to that of the above-described insulating film 40. The laminated film 56 is formed in a manner similar to that of the above-described laminated film 42.

The opening portions 60a to 60c exposing the upper surfaces of the ring patterns 52a to 52c, respectively, and the opening portions 62a to 62c connected to upper portions of the opening portions 60a to 60c, respectively, are formed in the interlayer insulating film 58 in the peripheral region 4 by using photolithography. The opening portion 60a and the opening portion 62a constitute the groove 64a. The opening portion 60b and the opening portion 62b constitute the groove 64b. The opening portion 60c and the opening portion 62c constitute the groove 64c. The grooves 64a to 64c are formed in a manner similar to those of the above-described grooves 50a to 50c. At this time, a contact hole 60d reaching the wiring 52e and the groove 62d connected to the upper portion of the contact hole 60d are formed in the interlayer insulating film 58 in the circuit region 2. The contact hole 60d is formed in a manner similar to that of the above-described contact hole 46d. The groove 62d is formed in a manner similar to that of the above-described groove 48d.

The ring patterns 66a to 66c are buried into the grooves 64a to 64c in a manner similar to those of the above-described ring patterns 52a to 52c. The ring patterns 66a to 66c are connected to the ring patterns 52a to 52c, respectively. At this time, the conductor plug 66d and the wiring 66e are buried into the contact hole 60d and the groove 62d in a manner similar to those of the above-described conductor plug 52d and the wiring 52e. The conductor plug 66d is connected to the wiring 52e.

Then, the interlayer insulating film 72 including the insulating film 68 and the laminated film 70 is formed all over the surface. The insulating film 68 is formed in a manner similar to that of the above-described insulating film 40. The laminated film 70 is formed in a manner similar to that of the above-described laminated film 42.

The opening portions 74a to 74c exposing the upper surfaces of the ring patterns 66a to 66c, respectively, and the opening portions 76a to 76c connected to upper portions of the opening portions 74a to 74c, respectively, are formed in the interlayer insulating film 72 in the peripheral region 4 by using photolithography. The opening portion 74a and the opening portion 76a constitute the groove 78a. The opening portion 74b and the opening portion 76b constitute the groove 78b. The opening portion 74c and the opening portion 76c constitute the groove 78c. The grooves 78a to 78c are formed in a manner similar to those of the above-described grooves 50a to 50c. At this time, the contact hole 74d reaching the wiring 66e and the groove 76d connected to the upper portion of the contact hole 74d are formed in the interlayer insulating film 72 in the circuit region 2. The contact hole 74d is formed in a manner similar to that of the above-described contact hole 46d. The groove 76d is formed in a manner similar to that of the above-described groove 48d.

The ring patterns 80a to 80c are buried into the grooves 78a to 78c in a manner similar to those of the above-described ring patterns 52a to 52c. The ring patterns 80a to 80c are connected to the ring patterns 66a to 66c, respectively. At this time, the conductor plug 80d and the wiring 80e are buried into the contact hole 74d and the groove 76d in a manner similar to those of the above-described conductor plug 52d and the wiring 52e. The conductor plug 80d is connected to the wiring 66e.

The interlayer insulating film 86 including the insulating film 82 and the laminated film 84 is formed all over the surface. The insulating film 82 is formed in a manner similar to that of the above-described insulating film 40. The laminated film 84 is formed in a manner similar to that of the above-described laminated film 42.

The opening portions 88a to 88c exposing the upper surfaces of the ring patterns 80a to 80c, respectively, and opening portions 90a to 90c connected to upper portions of the opening portions 88a to 88c, respectively, are formed in the interlayer insulating film 86 in the peripheral region 4 by using photolithography. The opening portion 88a and the opening portion 90a constitute the groove 92a. The opening portion 88b and the opening portion 90b constitute the groove 92b. The opening portion 88c and the opening portion 90c constitute the groove 92c. The grooves 92a to 92c are formed in a manner similar to those of the above-described grooves 50a to 50c. At this time, the contact hole 88d reaching the wiring 80e and the groove 90d connected to the upper portion of the contact hole 88d are formed in the interlayer insulating film 86 in the circuit region 2. The contact hole 88d is formed in a manner similar to that of the above-described contact hole 46d. The groove 90d is formed in a manner similar to that of the above-described groove 48d.

The ring patterns 94a to 94c are buried into the grooves 92a to 92c in a manner similar to those of the above-described ring patterns 52a to 52c. The ring patterns 94a to 94c are connected to the ring patterns 80a to 80c, respectively. At this time, the conductor plug 94d and the wiring 94e are buried into the contact hole 88d and into the groove 90d in a manner similar to those of the above-described conductor plug 52d and the wiring 52e.

The first layer metal wiring 38d, the second layer metal wiring 52e, the third layer metal wiring 66e, the fourth layer metal wiring 80e, and the fifth layer metal wiring 94e may be referred to as lower layer wirings. The pitch of such lower layer wirings may be specified to be, for example, about 0.28 μm.

Then, the insulating film (Cu diffusion-preventing film, etching stopper film) 96 is formed all over the surface by, for example, the plasma CVD method (refer to FIG. 9G). As for the insulating film 96, for example, a SiC film (SiOC film) is formed. The SiC film is formed as the insulating film 96 because, as described above, diffusion of Cu may be prevented and, in addition, an improvement in stress migration resistance is facilitated. The film thickness of the insulating film 96 is specified to be, for example, about 70 nm.

A SiOC film is formed all over the surface by, for example, a plasma CVD method. The film thickness of the SiOC film is specified to be, for example, about 920 nm.

A TEOS film is formed all over the surface by, for example, the plasma CVD method. The film thickness of the TEOS film is specified to be, for example, about 30 nm. The SiOC film and the TEOS film constitute the laminated film 98. The insulating film 96 and the laminated film 98 constitute the interlayer insulating film 100.

The opening portions 102a to 102c exposing the upper surfaces of the ring patterns 94a to 94c and opening portions 104a to 104c connected to upper portions of the opening portions 102a to 102c are formed in the interlayer insulating film 100 in the peripheral region 4 by using photolithography. The opening portion 102a and the opening portion 104a constitute the groove 106a. The opening portion 102b and the opening portion 104b constitute the groove 106b. The opening portion 102c and the opening portion 104c constitute the groove 106c. The widths of the opening portions 102a to 102c are specified to be, for example, about 0.28 μm. The widths of the opening portions 104a to 104c are specified to be, for example, about 2.0 μm. The grooves 106a to 106c are formed in a manner similar to those of the above-described grooves 50a to 50c. At this time, the contact hole 102d reaching the wiring 94e and the groove 104d connected to the upper portion of the contact hole 102d are formed in the interlayer insulating film 100 in the circuit region 2. The diameter of the contact hole 102d is specified to be, for example, about 0.28 μm. The width of the groove 104d is specified to be, for example, about 0.28 μm. The contact hole 102d is formed in a manner similar to that of the above-described contact hole 46d. The groove 104d is formed in a manner similar to that of the above-described groove 48d.

The ring patterns 108a to 108c are buried into the grooves 106a to 106c in a manner similar to those of the above-described ring patterns 52a to 52c. The ring patterns 108a to 108c are connected to the ring patterns 94a to 94c, respectively. At this time, the conductor plug 108d and the wiring 108e are buried into the contact hole 102d and into the groove 104d in a manner similar to those of the above-described conductor plug 52d and the wiring 52e. The conductor plug 108d and the wiring 108e are formed integrally. The conductor plug 108d is connected to the wiring 94e.

The interlayer insulating film 114 including the insulating film 110 and the laminated film 112 is formed all over the surface. The insulating film 110 is formed in a manner similar to that of the above-described insulating film 96. The laminated film 112 is formed in a manner similar to that of the above-described laminated film 98.

The opening portions 116a to 116c exposing the upper surfaces of the ring patterns 106a to 106c and the opening portions 118a to 118c connected to upper portions of the opening portions 116a to 116c are disposed in the interlayer insulating film 114 in the peripheral region 4 by using photolithography. The opening portion 116a and the opening portion 118a constitute the groove 120a. The opening portion 116b and the opening portion 118b constitute the groove 120b. The opening portion 116c and the opening portion 118c constitute the groove 120c. The grooves 120a to 120c are formed in a manner similar to those of the above-described grooves 50a to 50c. At this time, the contact hole 116d reaching the wiring 108e and the groove 118d connected to the upper portion of the contact hole 116d are formed in the interlayer insulating film 114 in the circuit region 2. The contact hole 116d is formed in a manner similar to that of the above-described contact hole 46d. The groove 118d is formed in a manner similar to that of the above-described groove 48d.

The ring patterns 122a to 122c are buried into the grooves 120a to 120c in a manner similar to those of the above-described ring patterns 52a to 52c. The ring patterns 122a to 122c are connected to the ring patterns 108a to 108c, respectively. At this time, the conductor plug 122d and the wiring 122e are buried into the contact hole 116d and into the groove 118d provided with a barrier metal film, in a manner similar to those of the above-described conductor plug 52d and the wiring 52e.

The sixth layer metal wiring 108e and the seventh layer metal wiring 122e may be referred to as middle layer wirings. The pitch of such middle layer wirings may be specified to be, for example, about 0.56 μm.

Then, the insulating film (Cu diffusion-preventing film, etching stopper film) 124 is formed all over the surface by, for example, the plasma CVD method (refer to FIG. 9H). As for the insulating film 124, for example, a SiC film (SiOC film) is used. The film thickness of the insulating film 124 is specified to be, for example, about 70 nm.

The insulating film 126 is formed all over the surface by, for example, the CVD method. As for the insulating film 126, for example, a silicon oxide film is formed. The film thickness of the insulating film 126 is specified to be, for example, about 1,470 nm. The insulating film 124 and the insulating film 126 constitute the interlayer insulating film 128.

The opening portions 130a to 130c exposing the upper surfaces of the ring patterns 122a to 122c and opening portions 132a to 132c connected to upper portions of the opening portions 130a to 130c are formed in the interlayer insulating film 128 in the peripheral region 4 by using photolithography. The opening portion 130a and the opening portion 132a constitute the groove 134a. The opening portion 130b and the opening portion 132b constitute the groove 134b. The opening portion 130c and the opening portion 132c constitute the groove 134c. The widths of the opening portions 130a to 130c are specified to be, for example, about 0.42 μm. The widths of the opening portions 132a to 132c are specified to be, for example, about 2.0 μm. The grooves 134a to 134c are formed in a manner similar to those of the above-described grooves 50a to 50c. At this time, the contact hole 130d reaching the wiring 122e and the groove 132d connected to the upper portion of the contact hole 130d are formed in the interlayer insulating film 128 in the circuit region 2. The diameter of the contact hole 130d is specified to be, for example, about 0.42 μm. The width of the groove 132d is specified to be, for example, about 0.42 μm. The contact hole 130d is formed in a manner similar to that of the above-described contact hole 46d. The groove 132d is formed in a manner similar to that of the above-described groove 48d.

The ring patterns 136a to 136c are formed in the grooves 134a to 134c in a manner similar to those of the above-described ring patterns 52a to 52c. The ring patterns 136a to 136c are connected to the ring patterns 122a to 122c, respectively. At this time, the conductor plug 136d and the wiring 136e are buried into the contact hole 130d and into the groove 132d in a manner similar to those of the above-described conductor plug 52d and the wiring 52e. The conductor plug 136d and the wiring 136e are formed integrally. The conductor plug 136d is connected to the wiring 122e.

The interlayer insulating film (insulating layer) 142 including the insulating film 138 and the insulating film 140 is formed all over the surface. The insulating film 138 is formed in a manner similar to that of the above-described insulating film 124. The insulating film 140 is formed in a manner similar to that of the above-described laminated film 126.

The opening portions 144a to 144c exposing the upper surfaces of the ring patterns 136a to 136c and the opening portions 146a to 146c connected to upper portions of the opening portions 144a to 144c are formed in the interlayer insulating film 142 in the peripheral region 4 by using photolithography (refer to FIG. 9I). The widths of the opening portions 144a to 144c are specified to be, for example, about 0.42 μm. The widths of the opening portions 146a to 146c are specified to be, for example, about 2.0 μm. The opening portion 144a and the opening portion 146a constitute the groove 148a. The opening portion 144b and the opening portion 146b constitute the groove 148b. The opening portion 144c and the opening portion 146c constitute the groove 148c. The grooves 148a to 148c are formed in a manner similar to those of the above-described grooves 50a to 50c. At this time, the contact hole 144d reaching the wiring 136e and the groove 146d connected to the upper portion of the contact hole 144d are disposed in the interlayer insulating film 142 in the circuit region 2. The contact hole 144d is formed in a manner similar to that of the above-described contact hole 46d. The groove 146d is formed in a manner similar to that of the above-described groove 48d.

Then, a barrier metal film (not illustrated in the drawing) is formed all over the surface by, for example, a sputtering method. As for the barrier metal film, for example, a Ta film is formed. The film thickness of the barrier metal film is specified to be, for example, about 20 nm.

A seed layer is formed all over the surface by, for example, the sputtering method. As for the seed layer, for example, a Cu film is formed. The film thickness of the seed layer is specified to be, for example, about 140 nm.

As illustrated in FIG. 9J, the electrically conductive film 150 is formed all over the surface by, for example, an electrolytic plating method. As for the electrically conductive film 150, for example, a Cu film is formed. The electrically conductive film 150 is also formed in the grooves 148a to 148c, in the contact hole 144d, and in the grooves 146d.

Then, the electrically conductive film 150, the seed layer, and the barrier metal film are polished by, for example, the CMP method until the surface of the interlayer insulating film 142 is exposed. In this manner, the ring patterns 150a to 150c composed of Cu are buried into the grooves 148a to 148c, respectively. The ring patterns 150a to 150c are formed in such a way as to surround the circuit region 2. The ring patterns 150a to 150c are connected to the ring patterns 136a to 136c, respectively. The widths w1 (refer to FIG. 5) of the upper portions of the ring patterns 150a to 150c, that is, the portions buried in the opening portions 146a to 146c of the ring patterns 150a to 150c, are specified to be, for example, about 2.0 μm. At this time, the conductor plug 150d and the wiring 150e are buried into the contact hole 144d and into the groove 146d provided with the barrier metal film. In this manner, the ring patterns 150a to 150c, the conductor plug 150d, and the wiring 150e are formed by the dual damascene method.

The eighth layer metal wiring 136e and the ninth layer metal wiring 150e may be referred to as upper layer wirings. The pitch of such upper layer wirings may be specified to be, for example, about 0.84 μm.

Then, the insulating film (Cu diffusion-preventing film, etching stopper film) 152 is formed by, for example, the plasma CVD method (refer to FIG. 9L). As for the insulating film 152, for example, a SiC film (SiOC film) is formed. The film thickness of the insulating film 152 is specified to be, for example, about 70 nm.

The insulating film 154 is formed by, for example, the CVD method. The insulating film 154 is formed from, for example, a silicon oxide film. The film thickness of the insulating film 154 is specified to be, for example, about 1,400 nm. The insulating film 152 and the insulating film 154 constitute the interlayer insulating film (insulating layer) 156.

In this regard, in a downstream step, the contact hole 158d having a relatively small diameter is formed in the interlayer insulating film 156. In the case where the interlayer insulating film 156 is formed having an excessively large thickness, it is difficult to form the contact hole 158d having a relatively small diameter in the interlayer insulating film 156. From such a viewpoint, the thickness of the interlayer insulating film 156 is specified as described above.

In the present embodiment, the SiC film (SiOC film) is formed as the insulating film 152 because sufficient stress migration resistance is obtained. In the case where a SiCN film or a SiN film is used as the material for the insulating film 152, the adhesion to the interlayer insulating film 142 serving as a substrate becomes better, but sufficient stress migration resistance is not obtained sometimes. The adhesion of the SiC film to the interlayer insulating film 142 serving as a substrate is poorer than that of the SiCN film or the SiN film. However, an improvement of the stress migration resistance is facilitated. Therefore, in the present embodiment, the SiC film is used as the insulating film 152.

The surface of the interlayer insulating film 154 is polished by, for example, the CMP method so as to flatten the surface of the interlayer insulating film 154. In the present embodiment, since the widths of the upper portions of the ring patterns 150a to 150c are relatively large, relatively deep dishing may be formed on the upper surfaces of the ring patterns 150a to 150c. In this case, unevenness may be generated on the surface of the interlayer insulating film 154 because of the dishing on the upper surfaces of the ring patterns 150a to 150c. Consequently, in the present embodiment, the polishing for flattening the surface of the interlayer insulating film 154 is conducted.

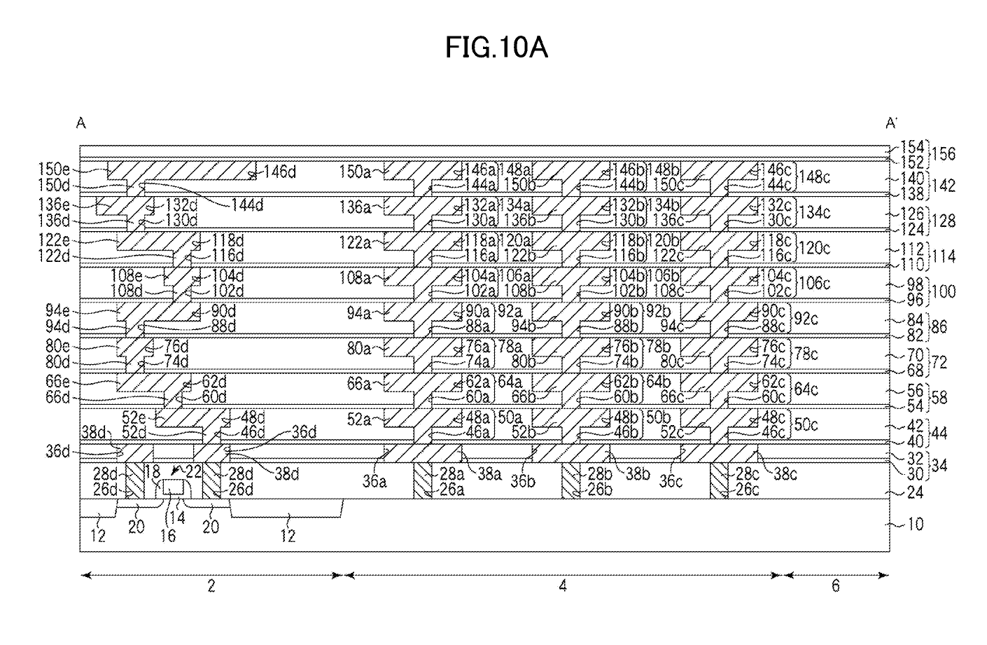

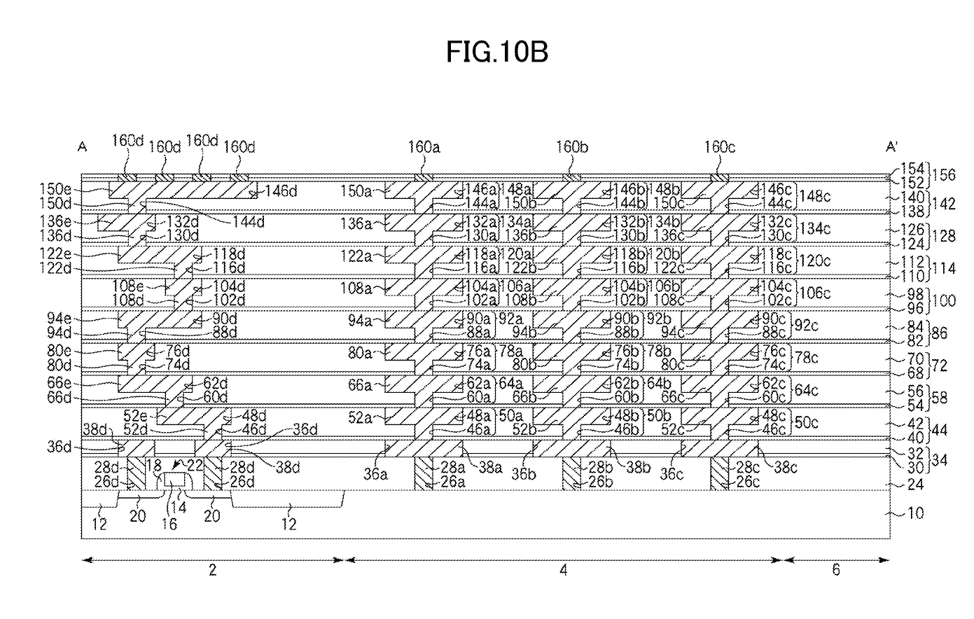

In this regard, in the case where the polishing for flattening the surface of the interlayer insulating film 154 is conducted, an upper layer portion of the interlayer insulating film 154 may be removed through polishing to a relatively large extent in the peripheral portion of the semiconductor wafer. FIG. 10A is a sectional view (No. 1) illustrating the state in which the upper layer portion of the interlayer insulating film 154 is removed through polishing to a relatively large extent. Such a phenomenon may occur in, for example, the peripheral portion of the semiconductor wafer, that is, in the hatched portion illustrated in FIG. 6.

Then, the grooves 158a to 158c exposing the upper surfaces of the ring patterns 150a to 150c, respectively, are formed in the interlayer insulating film 156 in the peripheral region 4 by using photolithography (refer to FIG. 9M). The widths of the grooves 158a to 158c are specified to be, for example, about 0.4 μm. The grooves 158a to 158c are disposed in such a way as to surround the circuit region 2. At this time, a plurality of contact holes 158d reaching the wiring 150e are formed in the interlayer insulating film 156 in the circuit region 2. The diameter of the contact holes 158d are specified to be, for example, about 0.5 μm.

A barrier metal film (not illustrated in the drawing) is formed all over the surface by, for example, the sputtering method. As for the barrier metal film, for example, a TiN film is used. The film thickness of the above-described TiN film is specified to be, for example, about 50 nm.

An electrically conductive film 160 is formed all over the surface by, for example, the CVD method (refer to FIG. 9N). As for the electrically conductive film 160, for example, a tungsten film is formed. The film thickness of the electrically conductive film 160 is specified to be, for example, about 300 nm.

The electrically conductive film 160 and the barrier metal film are polished by, for example, the CMP method until the surface of the interlayer insulating film 156 is exposed (refer to FIG. 9O). In this manner, the ring patterns 160a to 160c are buried into the grooves 158a to 158c. The ring patterns 160a to 160c are formed in such a way as to surround the circuit region 2. The ring patterns 160a to 160c are connected to the ring patterns 150a to 150c, respectively. The widths w2 (refer to FIG. 5) of the ring patterns 160a to 160c are specified to be, for example, about 0.4 μm. At this time, the conductor plugs 160d are buried into the contact holes 158d. The conductor plugs 160d are connected to the wiring 150e.

In this regard, in the polishing for burying the ring patterns 160a to 160c and the conductor plug 160d into the interlayer insulating film 154, an upper layer portion of the interlayer insulating film 154 may be removed through polishing to a relatively large extent in the peripheral portion of the semiconductor wafer. FIG. 10B is a sectional view (No. 2) illustrating the state in which the upper layer portion of the interlayer insulating film 154 is removed through polishing to a relatively large extent. Such a phenomenon may occur in, for example, the peripheral portion of the semiconductor wafer, that is, in the hatched portion illustrated in FIG. 6.

In the present embodiment, as described above, for example, tungsten is used as the material for the ring patterns 160a to 160c and the conductor plugs 160d. The reason for the use of tungsten as the material for the conductor plug 160d is that a tungsten film may be formed in a relatively fine contact hole 158d. Furthermore, in the case where Cu is used as the material for the conductor plug 160d, Cu may be corroded in etching of an aluminum film and the like in a downstream step, and poor contact may result. For such reasons, tungsten rather than Cu is used as the material for the conductor plug 160d.

The ring patterns 160a to 160c and the conductor plugs 160d are formed from the same electrically conductive film at the same time. Therefore, in the present embodiment, for example, tungsten is also used as the material for the ring patterns 160a to 160c.

Then, a barrier metal film (not illustrated in the drawing) is formed all over the surface by, for example, the sputtering method. As for such a barrier metal film, for example, a laminated film of a Ti film and a TiN film is used. The film thickness of the above-described Ti film is specified to be, for example, about 60 nm. The film thickness of the above-described TiN film is specified to be, for example, about 30 nm.

A metal film 162 is formed all over the surface by, for example, the sputtering method. As for the above-described metal film 162, for example, a laminated film of an aluminum film and a TiN film is formed. The film thickness of the above-described aluminum film is specified to be, for example, about 1,000 nm. The film thickness of the above-described TiN film is specified to be, for example, about 50 nm.

A photoresist film 180 is formed all over the surface by, for example, a spin coating method. Thereafter, the photoresist film 180 is patterned by using photolithography (refer to FIG. 9P). The photoresist film 180 is formed into the two-dimensional shape of the ring patterns 162a to 162c and the two-dimensional shape of the electrode pad 162d.

Then, the metal film 162 and the barrier metal film are etched while the photoresist film 180 is used as a mask (refer to FIG. 9Q). In this manner, the ring patterns 162a to 162c composed of the barrier metal film and the metal film 162 are formed on the interlayer insulating film 156 in the peripheral region 4. The ring patterns 162a to 162c are formed in such a way as to surround the circuit region 2. The ring patterns 162a to 162c are connected to the ring patterns 160a to 160c, respectively. The widths of the ring patterns 162a to 162c are specified to be larger than the widths of the ring patterns 150a to 150c buried in the interlayer insulating film 142. Specifically, the widths w3 (refer to FIG. 5) of the ring patterns 162a to 162c are specified to be, for example, about 3.0 μm. Both side portions along the longitudinal direction of the ring patterns 162a to 162c are located in such a way as to protrude toward the outside by d1 from both side portions along the longitudinal direction of the ring patterns 150a to 150c (refer to FIG. 5). The distance d1 is specified to be, for example, about 0.5 μm. At this time, the electrode pad 162d composed of the barrier metal film and the metal film 162 is formed on the interlayer insulating film 156 in the circuit region 2.

Thereafter, the photoresist film 180 is peeled (refer to FIG. 9R).

In this regard, the ring patterns 162a to 162c are formed on the ring patterns 160a to 160c for the purpose of preventing the ring patterns 160a to 160c from being etched in the formation of the electrode pad 162d, as described above. If even the ring patterns 160a to 160c are etched, it becomes difficult to ensure sufficient moisture resistance. For this reason, in the present embodiment, the ring patterns 162a to 162c are formed on the ring patterns 160a to 160c.

Furthermore, the ring patterns 162a to 162c are not integrated and the ring patterns 162a to 162c are isolated from each other for the purpose of ensuring the moisture resistance even when cracking occurs in the ring pattern, as described above. That is, in the case where the ring patterns 162a to 162c are formed integrally, when cracking occurs in the ring pattern, cracking is propagated and, thereby, it may become difficult to ensure the moisture resistance. In the case where the ring patterns 162a to 162c are formed while being isolated from each other, even when cracking occurs in any one of the ring patterns 162a to 162c, cracking is not propagated to other ring patterns 162a to 162c. Consequently, the moisture resistance may be ensured reliably. For this reason, in the present embodiment, the ring patterns 162a to 162c are isolated from each other.

In this manner, the moisture-resistant ring 8a is formed from the ring patterns 28a, 38a, 52a, 66a, 80a, 94a, 108a, 122a, 136a, 150a, 160a, and 162a. In this manner, the moisture-resistant ring 8b is formed from the ring patterns 28b, 38b, 52b, 66b, 80b, 94b, 108b, 122b, 136b, 150b, 160b, and 162b. In this manner, the moisture-resistant ring 8c is formed from the ring patterns 28c, 38c, 52c, 66c, 80c, 94c, 108c, 122c, 136c, 150c, 160c, and 162c.

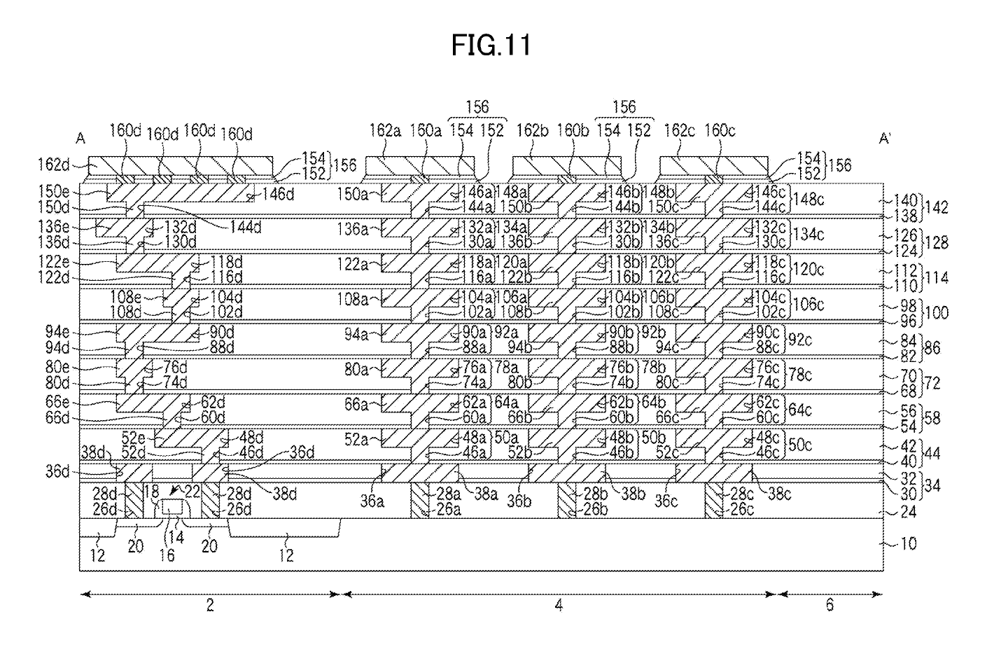

In this regard, in formation of the ring patterns 162a to 162c and the electrode pad 162d through etching, an upper layer portion of the interlayer insulating film 154 in the portion exposed at the peripheries of the ring patterns 162a to 162c and the electrode pad 162d may be over etched. FIG. 11 is a sectional view illustrating the state in which an upper layer portion of the interlayer insulating film 154 is removed through not only polishing, but also etching to a relatively large extent. Such a phenomenon may occur in the peripheral portion of the semiconductor wafer, that is, in the hatched portion illustrated in FIG. 6.

However, in the present embodiment, the two side portions along the longitudinal direction of the ring patterns 162a to 162c do not overlap the ring patterns 150a to 150c two-dimensionally. That is, in the present embodiment, the two side portions along the longitudinal direction of the ring patterns 162a to 162c are located outside the regions just above the ring patterns 150a to 150c. Consequently, in the present embodiment, even when the interlayer insulating film 154 is removed excessively through polishing, etching, or the like, as illustrated in FIG. 11, the condition, in which at least a part of the interlayer insulating film 156 of the portions just below the ring patterns 162a to 162c is in contact with the interlayer insulating film 142, is maintained. Since the adhesion between the interlayer insulating film 156 and the interlayer insulating film 142 is relatively good, the interlayer insulating film 156 in contact with the interlayer insulating film 142 is not peeled off the interlayer insulating film 142. Consequently, according to the present embodiment, even when the interlayer insulating film 156 exposed at the peripheries of the ring patterns 162a to 162c is removed excessively through polishing, etching, or the like, peeling of the ring patterns 162a to 162c may be prevented.

Then, the silicon oxide film 164 is formed all over the surface by, for example, the CVD method. The film thickness of the silicon oxide film 164 is specified to be, for example, about 1,400 nm.

The silicon nitride film 166 is formed all over the surface by, for example, the CVD method. The film thickness of the silicon nitride film 166 is specified to be, for example, about 500 nm. The silicon oxide film 164 and the silicon nitride film 166 constitute the protective film 168.

The opening portion 170 exposing the upper surface of the electrode pad 162d is formed in the protective film 168 by using photolithography. The above-described opening portion 170 makes it possible to connect the electrode pad 162d to the outside.

The protective film 172 is formed all over the surface by, for example, the spin coating method. As for the protective film 172, for example, a photosensitive polyimide film is formed. The film thickness of the protective film 172 is specified to be, for example, about 2.0 nm.

The opening portion 174 exposing the upper surface of the electrode pad 162d is formed in the protective film 172 by using photolithography. The above-described opening portion 174 makes it possible to connect the electrode pad 162d to the outside.

Then, the semiconductor wafer 10 is diced along the scribe line region 6. For example, the semiconductor wafer 10 is cut along the portion indicated by an alternate long and short dashed lines in FIG. 9S.

In this manner, the semiconductor device according to the present embodiment is produced (refer to FIG. 9T).

Thereafter, the solder bump 176 may be formed on the electrode pad 162d (refer to FIG. 8A). Alternatively, the bonding wire 178 may be connected to the electrode pad 162d (refer to FIG. 8B).

As described above, according to the present embodiment, the two side portions along the longitudinal direction of the ring patterns 162a to 162c do not overlap the ring patterns 150a to 150c two-dimensionally. That is, in the present embodiment, the two side portions along the longitudinal direction of the ring patterns 162a to 162c are located outside the regions just above the ring patterns 150a to 150c. Consequently, in the present embodiment, even when the interlayer insulating film 154 is removed excessively through polishing, etching, or the like, the condition, in which at least a part of the interlayer insulating film 156 of the portions just below the ring patterns 162a to 162c is in contact with the interlayer insulating film 142, is maintained. Since the adhesion between the interlayer insulating film 156 and the interlayer insulating film 142 is relatively good, the interlayer insulating film 156 in contact with the interlayer insulating film 142 is not peeled off the interlayer insulating film 142. Hence, according to the present embodiment, even when the interlayer insulating film 156 exposed at the peripheries of the ring patterns 162a to 162c is removed excessively through polishing, etching, or the like, peeling of the ring patterns 162a to 162c may be prevented. Moreover, according to the present embodiment, since the plurality of moisture-resistant rings 8a to 8c are disposed, intrusion of moisture into the circuit region 2 may be prevented reliably. Furthermore, since the ring patterns 162a to 162c are isolated from each other, even when cracking occurs in any one of the ring patterns 162a to 162c, cracking is not propagated. Consequently, intrusion of moisture into the circuit region 2 may be prevented reliably.

### Second Embodiment

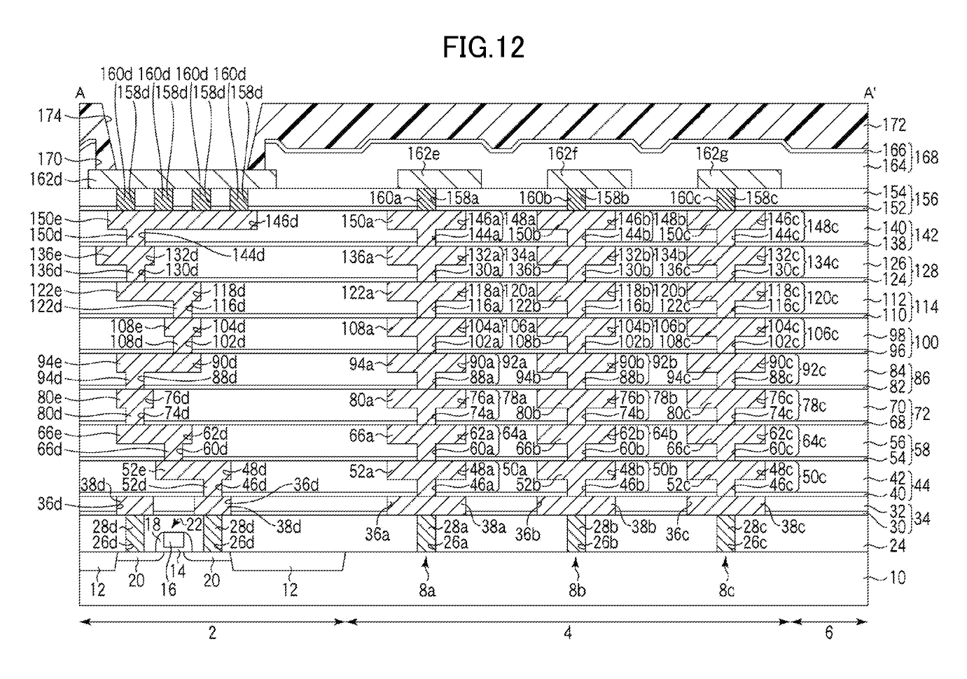

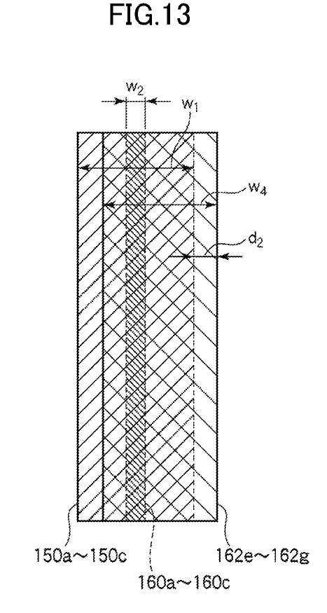

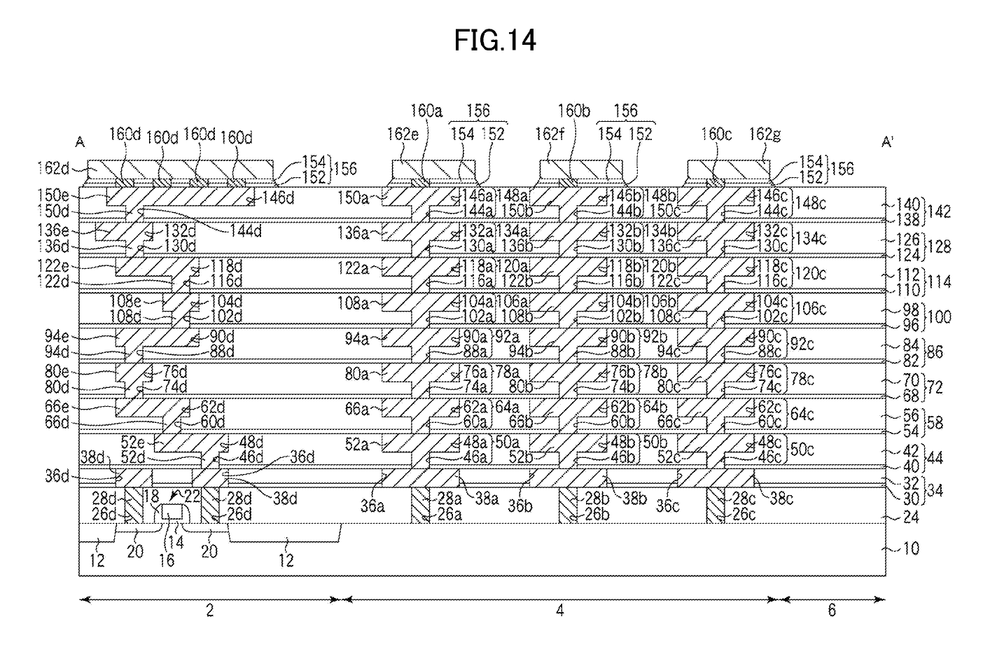

A semiconductor device according to a second embodiment will be described with reference to FIGS. 12 and 14. FIG. 12 is a sectional view illustrating a semiconductor device according to the present embodiment. FIG. 13 is a plan view illustrating a part of the semiconductor device according to the present embodiment. FIG. 14 is a sectional view illustrating the state in which an upper layer portion of an interlayer insulating film is removed through not only polishing, but also etching to a relatively large extent. The same constituents as those in the semiconductor device and the method for manufacturing the semiconductor device illustrated in FIGS. 1 to 11 are indicated by the same reference numerals as those set forth above and explanations thereof will not be provided or be simplified.

The main feature of the semiconductor device according to the present embodiment is that one side portion of the two side portions along the longitudinal direction of each of the ring patterns 162e to 162g does not overlap the ring patterns 150a to 150c two-dimensionally.

As illustrated in FIG. 12, ring patterns 162e to 162g are disposed on the interlayer insulating film 156 in the peripheral region 4. The ring patterns 162e to 162g are disposed in such a way as to surround the circuit region 2. The ring patterns 162e to 162g are connected to the ring patterns 160a to 160c, respectively. The ring patterns 162e to 162g are formed from a barrier metal film (not illustrated in the drawing) and a metal film (not illustrated in the drawing) disposed on the barrier metal film. As for such a barrier metal film, for example, a laminated film of a Ti film and a TiN film is used. The film thickness of the above-described Ti film is specified to be, for example, about 60 nm. The film thickness of the above-described TiN film is specified to be, for example, about 30 nm. As for the above-described metal film, for example, a laminated film of an aluminum film and a TiN film is used. The film thickness of the above-described aluminum film is specified to be, for example, about 1,000 nm. The film thickness of the above-described TiN film is specified to be, for example, about 50 nm. The widths w4 of the ring patterns 162e to 162g are specified to be equal to the widths w1 of the ring patterns 150a to 150c buried in the interlayer insulating film 142. Specifically, the widths w1 of the ring patterns 150a to 150c and the widths w4 of the ring patterns 162e to 162g (refer to FIG. 13) are specified to be, for example, about 2.0 μm. One side portion of the two side portions along the longitudinal direction of each of the ring patterns 162e to 162g is located in such a way as to protrude toward the outside by d2 from one of the two side portions along the longitudinal direction of each of the ring patterns 150a to 150c (refer to FIG. 13). The distance d2 is specified to be, for example, about 0.5 μm. The other side portion of the two side portions along the longitudinal direction of each of the ring patterns 162e to 162g overlaps the side portion of each of the ring patterns 150a to 150c two-dimensionally.

As described above, it is possible that one side portion of the two side portions along the longitudinal direction of each of the ring patterns 162e to 162g does not overlap the ring patterns 150a to 150c two-dimensionally.

In the present embodiment as well, at least one of the two side portions along the longitudinal direction of each of the ring patterns 162e to 162g is located outside the regions just above the ring patterns 150a to 150c. Consequently, even when the interlayer insulating film 154 is removed excessively through polishing, etching, or the like, the condition, in which at least a part of the interlayer insulating film 156 of the portions just below the ring patterns 162e to 162g is in contact with the interlayer insulating film 142, is maintained, as illustrated in FIG. 14. Since the adhesion between the interlayer insulating film 156 and the interlayer insulating film 142 is relatively good, the interlayer insulating film 156 in contact with the interlayer insulating film 142 is not peeled off the interlayer insulating film 142. Hence, according to the present embodiment as well, even when the interlayer insulating film 156 exposed at the peripheries of the ring patterns 162e to 162g is removed excessively through polishing, etching, or the like, peeling of the ring patterns 162a to 162c may be prevented.

### Third Embodiment

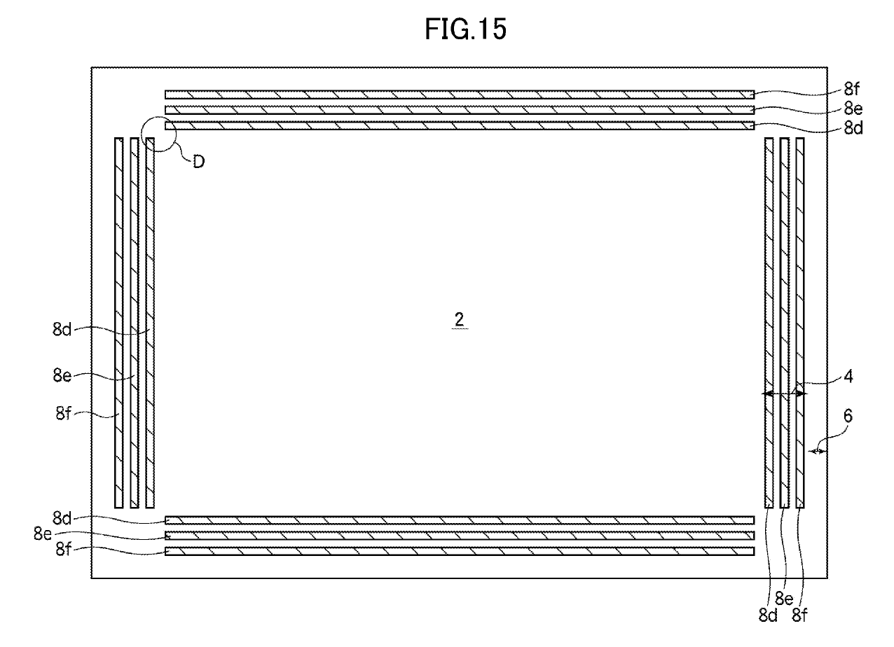

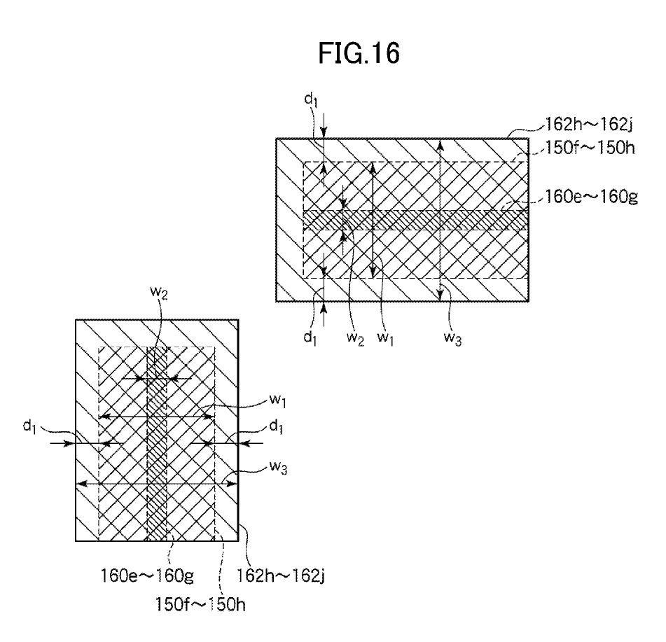

A semiconductor device according to a third embodiment will be described with reference to FIGS. 15 and 16. FIG. 15 is a plan view illustrating the semiconductor device according to the present embodiment. The same constituents as those in the semiconductor device and the method for manufacturing the semiconductor device illustrated in FIGS. 1 to 14 are indicated by the same reference numerals as those set forth above and explanations thereof will not be provided or be simplified.

The main feature of the semiconductor device according to the present embodiment is that the moisture-resistant ring is formed discontinuously (intermittently).

As illustrated in FIG. 15, in the present embodiment, moisture-resistant rings 8d to 8f (guard ring, seal ring, moisture-resistant wall) are disposed in the peripheral region 4 surrounding the circuit region 2. The moisture-resistant ring 8d is disposed discontinuously in such a way as to surround the circuit region 2. The moisture-resistant ring 8e is disposed discontinuously in such a way as to surround the moisture-resistant ring 8d. The moisture-resistant ring 8f is disposed discontinuously in such a way as to surround the moisture-resistant ring 8e. The moisture-resistant rings 8d to 8f are cut in the regions close to corner portions of the semiconductor substrate 10.

In the first embodiment and the second embodiment, each of ring patterns for forming the moisture-resistant rings 8a to 8c is disposed continuously in accordance with the moisture-resistant rings 8a to 8c. On the other hand, in the present embodiment, each of ring patterns (moisture-resistant wall patterns) for forming the moisture-resistant rings 8d to 8f is disposed discontinuously in accordance with the moisture-resistant rings 8d to 8f.

FIG. 16 is a magnified plan view of a portion in a circle D illustrated in FIG. 15.

As illustrated in FIG. 16, ring patterns 150f to 150h are buried in the interlayer insulating film 142 in the peripheral region 4. The ring pattern 150f is a part of the moisture-resistant ring 8d. The ring pattern 150g is a part of the moisture-resistant ring 8e. The ring pattern 150h is a part of the moisture-resistant ring 8f. The ring patterns 150f to 150h are disposed in such a way as to surround the circuit region 2. The ring patterns 150f to 150h are not disposed in the regions close to corner portions of the semiconductor substrate 10 and are discontinuous. The widths w1 of the ring patterns 150f to 150h are specified to be, for example, about 2.0 μm.

Ring patterns 160e to 160g are buried in the interlayer insulating film 156 in the peripheral region 4. The ring pattern 160e is a part of the moisture-resistant ring 8d. The ring pattern 160f is a part of the moisture-resistant ring 8e. The ring pattern 160g is a part of the moisture-resistant ring 8f. The ring patterns 160e to 160g are disposed in such a way as to surround the circuit region 2. The ring patterns 160e to 160g are not disposed in the regions close to corner portions of the semiconductor substrate 10 and are discontinuous. The ring patterns 160e to 160g are connected to the ring patterns 150f to 150h, respectively. The widths w2 of the ring patterns 160e to 160g are specified to be, for example, about 0.4 μm.

Ring patterns 162h to 162j are disposed on the interlayer insulating film 156 in the peripheral region 4. The ring pattern 162h is a part of the moisture-resistant ring 8d. The ring pattern 162i is a part of the moisture-resistant ring 8e. The ring pattern 162j is a part of the moisture-resistant ring 8f. The ring patterns 162h to 162j are disposed in such a way as to surround the circuit region 2. The ring patterns 162h to 162j are not disposed in the regions close to corner portions of the semiconductor substrate 10 and are discontinuous. The ring patterns 162h to 162j are connected to the ring patterns 160e to 160g, respectively. The widths w3 of the ring patterns 162h to 162j are specified to be, for example, about 3.0 μm.

Both side portions along the longitudinal direction of the ring patterns 162h to 162j are located in such a way as to protrude toward the outside by d1 from both side portions along the longitudinal direction of the ring patterns 150f to 150h (refer to FIG. 16). The distance d1 is specified to be, for example, about 0.5 μm.

The two end portions along the longitudinal direction of the ring patterns 162h to 162j are located in such a way as to protrude toward the outside from the two end portions along the longitudinal direction of the ring patterns 150f to 150h. The two end portions of the ring patterns 162h to 162j are not overlapped with the two end portions of the ring patterns 150f to 150h two-dimensionally in order to ensure sufficiently the contact place between the interlayer insulating film 156 and the interlayer insulating film 142 in the case where the interlayer insulating film 154 is removed excessively.

As described above, the moisture-resistant rings 8d to 8f may be disposed discontinuously. Even when the moisture-resistant rings 8d to 8f are disposed discontinuously, it is possible to obtain a moisture-resistant effect to some extent.

Here, an example, in which the ring patterns 162h to 162j are not disposed in the regions close to corner portions of the semiconductor substrate 10 and are discontinuous, has been explained, although not limited to this. The ring patterns 162h to 162j may be disposed in the regions close to corner portions of the semiconductor substrate 10 in such a way that no isolation occurs. That is, each of the ring patterns 162h to 162j may be formed continuously.

In the present embodiment, the moisture-resistant rings 8d to 8f are made to be discontinuous at the corner portions of the semiconductor substrate 10 for the purpose of preventing an occurrence of poor burying in the case where the Cu film or the tungsten film is buried into the groove by the CMP method. The ring patterns 162h to 162j are formed by etching the electrically conductive film after the electrically conductive film serving as the ring pattern is formed. Therefore, such poor burying does not occur. Consequently, it is not necessary that the ring patterns 162h to 162j are made to be discontinuous at the corner portions of the semiconductor substrate 10 intentionally. Hence, each of the ring patterns 162h to 162j may be formed continuously.

### Modified Embodiment

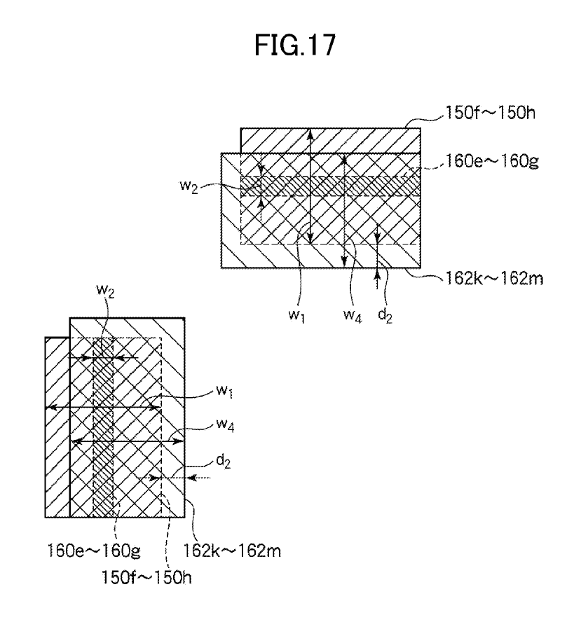

Next, a modified embodiment of a semiconductor device according to the present embodiment will be described with reference to FIGS. 15 and 17. FIG. 17 is a plan view illustrating the semiconductor device according to the present modified embodiment.

The main feature of the semiconductor device according to the present modified embodiment is that one side portion of the two side portions along the longitudinal direction of each of the ring patterns 162k to 162m do not overlap the ring patterns 150f to 150h two-dimensionally.

The moisture-resistant rings 8d to 8f are disposed in the peripheral region 4 surrounding the circuit region 2 (refer to FIG. 15). The moisture-resistant ring 8d is disposed discontinuously in such a way as to surround the circuit region 2. The moisture-resistant ring 8e is disposed discontinuously in such a way as to surround the moisture-resistant ring 8d. The moisture-resistant ring 8f is disposed discontinuously in such a way as to surround the moisture-resistant ring 8e. The moisture-resistant rings 8d to 8f are cut in the regions close to corner portions of the semiconductor substrate 10.

In the first embodiment and the second embodiment, each of ring patterns for forming the moisture-resistant rings 8a to 8c is disposed continuously in accordance with the moisture-resistant rings 8a to 8c. On the other hand, in the present modified embodiment, each of ring patterns for forming the moisture-resistant rings 8d to 8f is disposed discontinuously in accordance with the moisture-resistant rings 8d to 8f.

FIG. 17 is a magnified plan view of a portion in a circle D illustrated in FIG. 15.

As illustrated in FIG. 17, the ring patterns 162k to 162m are formed on the interlayer insulating film 156 in the peripheral region 4. The ring patterns 162k to 162m are disposed in such a way as to surround the circuit region 2. The ring patterns 162k to 162m are connected to the ring patterns 160e to 160g, respectively. The ring patterns 162k to 162m are formed from the same electrically conductive film as that for the electrode pad 162d. The widths w4 of the ring patterns 162k to 162m are specified to be equal to the widths w1 of the ring patterns 150f to 150h buried in the interlayer insulating film 142. Specifically, the widths w1 of the ring patterns 150f to 150h and the widths w4 of the ring patterns 162k to 162m are specified to be, for example, about 2.0 μm. One side portion of the two side portions along the longitudinal direction of each of the ring patterns 162k to 162m is located in such a way as to protrude toward the outside by d2 from one of the two side portions along the longitudinal direction of each of the ring patterns 150f to 150h. The distance d2 is specified to be, for example, about 0.5 μm. The other side portion of the two side portions along the longitudinal direction of each of the ring patterns 162k to 162m is overlapped with the side portion of the ring patterns 150f to 150h two-dimensionally.

Furthermore, the two end portions along the longitudinal direction of the ring patterns 162k to 162m are located in such a way as to protrude toward the outside from the two end portions along the longitudinal direction of the ring patterns 150f to 150h. In the present modified embodiment, three sides among the sides of each of the ring patterns 162k to 162m do not overlap the ring patterns 150f to 150h two-dimensionally. The two end portions of the ring patterns 162k to 162m are not overlapped with the ring patterns 150f to 150h two-dimensionally in order to ensure sufficiently the contact place between the interlayer insulating film 156 and the interlayer insulating film 142 in the case where the interlayer insulating film 154 is removed excessively.

As described above, it is possible that one side portion of the two side portions along the longitudinal direction of each of the ring patterns 162k to 162m do not overlap the ring patterns 150f to 150h two-dimensionally.

Here, an example, in which the ring patterns 162k to 162m are not disposed in the regions close to corner portions of the semiconductor substrate 10 and are discontinuous, has been explained, although not limited to this. The ring patterns 162k to 162m may be disposed in the regions close to corner portions of the semiconductor substrate 10 in such a way that no isolation occurs. That is, each of the ring patterns 162k to 162m may be formed continuously.

As described above, in the present embodiment, the moisture-resistant rings 8d to 8f are made to be discontinuous at the corner portions of the semiconductor substrate 10 for the purpose of preventing an occurrence of poor burying in the case where the Cu film or the tungsten film is buried into the groove by the CMP method. The ring patterns 162k to 162m are formed by etching the electrically conductive film after the electrically conductive film serving as the ring pattern is formed. Therefore, such poor burying does not occur. Consequently, it is not necessary that the ring patterns 162k to 162m are made to be discontinuous at the corner portions of the semiconductor substrate 10 intentionally. Hence, each of the ring patterns 162k to 162m may be formed continuously.

[Modified Embodiments]

Various modifications not limited to the above-described embodiments may be conducted.

For example, in the above-described embodiment, the case where Cu is used as the material for the ring patterns 150a to 150c is explained as an example. However, the material for the ring patterns 150a to 150c is not limited to Cu. For example, a Cu-containing material, e.g., a Cu alloy, may be used as the material for the ring patterns 150a to 150c. The above-described embodiment is effective for any case where a material exhibiting not always good adhesion to the insulating film 152 is used as the material for the ring patterns 150a to 150c.

Furthermore, in the above-described embodiment, the case where the adhesion between the ring patterns 150a to 150c and the insulating film 152 is poor is explained as an example. However, the adhesion between the ring patterns 150a to 150c and the insulating film 152 may be good. In the case where the adhesion between the ring patterns 150a to 150c and the insulating film 152 is good, peeling of the ring patterns 160a to 160c and 162a to 162c may be prevented more reliably. For example, as for the insulating film 152, a SiN film, a SiON film, a SiCF film, or the like may be used.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A method for manufacturing a semiconductor device, comprising:
forming a first insulating layer on a semiconductor substrate;
forming a first groove, which surrounds a circuit region on the semiconductor substrate, and a second groove, which surrounds the first groove, in the first insulating layer in a peripheral region surrounding the circuit region;
burying a first pattern, which serves as a part of a first moisture-resistant ring, into the first groove and burying a second pattern, which serves as a part of a second moisture-resistant ring, into the second groove;
forming a second insulating layer on the first insulating layer, the first pattern, and the second pattern;
forming a third groove, which surrounds the circuit region, which reaches the first pattern and which has a width smaller than that of the first pattern, and a fourth groove, which surrounds the third groove, which reaches the second pattern and which has a width smaller than that of the second pattern, in the second insulating layer;
burying a third pattern, which serves as a part of the first moisture-resistant ring, into the third groove and burying a fourth pattern, which serves as a part of the second moisture-resistant ring, into the fourth groove; and
forming a fifth pattern, which surrounds the circuit region and which is connected to the third pattern, in which one of two first side portions nearer from the circuit region than the other of two first side portions is retracted from an edge of the first pattern near the circuit region and the other of two first side portions farther from the circuit region than one of two first side portions is protruded from the first pattern in a plan view, and which serves as a part of the first moisture-resistant ring, and in addition, forming a sixth pattern, which surrounds the fifth pattern and which is connected to the fourth pattern, in which one of two second side portions nearer from the circuit region than the other of two second side portions is retracted from an edge of the second pattern near the circuit region and the other of two second side portions farther from the circuit region than one of two second side portions is protruded from the second pattern in a plan view, which serves as a part of the second moisture-resistant ring, and which is isolated from the fifth pattern, on the second insulating layer.

2. The method for manufacturing a semiconductor device according to claim 1,
wherein the width of the fifth pattern is larger than the width of the first pattern, and the width of the sixth pattern is larger than the width of the second pattern.

3. The method for manufacturing a semiconductor device according to claim 1,
wherein the burying of the first pattern and the second pattern comprises forming a first electrically conductive film including copper into the first groove, into the second groove, and on the first insulating layer; and burying the first pattern formed from the first electrically conductive film into the first groove and burying the second pattern formed from the first electrically conductive film into the second groove by polishing the first electrically conductive film until the surface of the first insulating layer is exposed, and
the forming of the second insulating layer comprises forming a SiC film in contact with the first pattern and the second pattern.

4. The method for manufacturing a semiconductor device according to claim 1,
wherein in the forming of the first groove and the second groove, the first groove, in which the width of an upper portion is larger than the width of a lower portion, and the second groove, in which the width of an upper portion is larger than the width of a lower portion, are formed, and
in the burying of the first pattern and the second pattern into the first insulating layer, the first pattern, in which the width of the upper portion is larger than the width of the lower portion, and the second pattern, in which the width of the upper portion is larger than the width of the lower portion, are buried into the first insulating layer.

5. The method for manufacturing a semiconductor device according to claim 1,
wherein in the forming of the first groove and the second groove, a fifth groove is further formed in the first insulating layer in the circuit region,
in the burying of the first pattern and the second pattern, an wiring is further buried in the fifth groove,
in the forming of the third groove and the fourth groove, a contact hole reaching the wiring is further formed in the second insulating layer in the circuit region,
in the burying of the third pattern and the fourth pattern, an electrically conductive plug is further buried in the contact hole, and
in the forming of the fifth pattern and the sixth pattern, an electrode pad connected to the electrically conductive plug is further formed on the second insulating layer in the circuit region.

6. The method for manufacturing a semiconductor device according to claim 1, further comprising:
flattening the surface of the second insulating layer through polishing after the forming of the second insulating layer and before the forming of the third groove and the fourth groove.

7. The method for manufacturing a semiconductor device according to claim 1,
wherein the forming of the third pattern and the fourth pattern comprises forming a second electrically conductive film into the third groove, into the fourth groove, and on the second insulating layer, and burying the third pattern formed from the second electrically conductive film into the third groove and, in addition, burying the fourth pattern formed from the second electrically conductive film into the fourth groove by polishing the second electrically conductive film until the surface of the second insulating layer is exposed.

8. The method for manufacturing a semiconductor device according to claim 1,
wherein the forming of the fifth pattern and the sixth pattern comprises forming a third electrically conductive film on the third pattern, on the fourth pattern, and on the second insulating layer, and forming the fifth pattern formed from the third electrically conductive film and the sixth pattern formed from the third electrically conductive film by etching the third electrically conductive film.

9. The method for manufacturing a semiconductor device according to claim 1,
wherein a first area enclosed by the fifth pattern is larger than a second area enclosed by the first pattern in a plan view.

10. The method for manufacturing a semiconductor device according to claim 7,
wherein the second electrically conductive film includes tungsten.

11. The method for manufacturing a semiconductor device according to claim 8,
wherein the third electrically conductive film includes aluminum.
